(19) United States
(12) Patent Application Publication
(10) Pub. No.: US 2026/0305144 A1
(43) Pub. Date: Oct. 1, 2026

(54) DISPLAY DEVICE AND ELECTRONIC DEVICE INCLUDING THE SAME

(71) Applicant: Samsung Display Co., Ltd., Yongin-si (KR)

(72) Inventors: Chanyoung Kim, Yongin-si (KR); Choongyoul Im, Yongin-si (KR); Changwook Kim, Yongin-si (KR); Changhyun Back, Yongin-si (KR); Eunje Jang, Yongin-si (KR)

(21) Appl. No.: 19/564,879

(22) Filed: Mar. 12, 2026

(30) Foreign Application Priority Data
Mar. 26, 2025 (KR) 10-2025-0039046

(51) Int. Cl. H10K 59/80; H10H 29/37; H10H 29/85; H10H 29/855; H10K 59/122; H10K 59/38; H10K 59/65

(52) U.S. Cl. CPC H10K 59/8792; H10H 29/37; H10H 29/8517; H10H 29/8552; H10K 59/122; H10K 59/38; H10K 59/65

(57) ABSTRACT

A display device includes a first display area and a second display area, in which a plurality of first transmission areas are disposed in the first display area, and a plurality of second transmission areas are disposed in the second display area, the display device including a substrate, a pixel electrode disposed on the substrate, an emission layer disposed on the pixel electrode, a bank layer covering at least a portion of the pixel electrode, and a light-blocking layer disposed on the bank layer, where an opening is defined in each of the bank layer and the light-blocking layer, at positions overlapping the plurality of first transmission areas, and where an opening is defined in one of the bank layer and the light-blocking layer, at positions overlapping the plurality of second transmission areas.

This application claims priority to Korean Patent Application No. 10-2025-0039046, filed on Mar. 26, 2025, and all the benefits accruing therefrom under 35 U.S.C. §119, the content of which in its entirety is herein incorporated by reference.

### BACKGROUND

### 1. Field

Embodiments relate to an apparatus, and more particularly, to a display device and an electronic device including the same.

### 2. Description of the Related Art

Mobile electronic devices are widely used. As mobile electronic devices, recently, tablet personal computers have been widely used as well as miniaturized electronic devices such as mobile phones.

To support various functions, for example, to provide a user with visual information such as images, the mobile electronic devices include a display device. Recently, as the other parts for driving display devices are being miniaturized, the proportion taken up by display devices in electronic devices is being gradually increased and structures capable of being bent to a preset angle from a flat state are also under development.

### SUMMARY

The disclosure is characterized by reducing a difference in external light reflectance for each region in a display area of a display device.

However, such an objective is just an example, and the disclosure is not limited thereto.

Additional features will be set forth in part in the description which follows and, in part, will be apparent from the description, or may be learned by practice of the presented embodiments of the disclosure.

In an embodiment of the disclosure, a display device includes a first display area and a second display area in which a plurality of first transmission areas are included in the first display area, and a plurality of second transmission areas are included in the second display area, includes a substrate, a pixel electrode disposed on the substrate, an emission layer disposed on the pixel electrode, a bank layer covering at least a portion of the pixel electrode, and a light-blocking layer disposed on the bank layer, where an opening is defined in each of the bank layer and the light-blocking layer, at positions overlapping the plurality of first transmission areas, and where an opening is defined in one of the bank layer and the light-blocking layer, at positions overlapping the plurality of second transmission areas.

In an embodiment, external light reflectance in a first transmission area of the plurality of first transmission areas may be greater than external light reflectance in a second transmission area of the plurality of second transmission areas.

In an embodiment, infrared rays may be transmitted through each of a first transmission area of the plurality of first transmission areas and a second transmission area of the plurality of second transmission areas.

In an embodiment, a size of the plurality of second transmission areas may gradually decrease with increasing distance from the first display area.

In an embodiment, a number of the plurality of second transmission areas per unit area may gradually decrease with increasing distance from the first display area.

In an embodiment, the second display area may include a second-1 display area, a second-2 display area, and a second-3 display area, which are arranged in order of increasing distance from the first display area, where the plurality of second transmission areas may include a plurality of second-1 transmission areas disposed in the second-1 display area, a plurality of second-2 transmission areas disposed in the second-2 display area, and a plurality of second-3 transmission areas disposed in the second-3 display area, where external light reflectance in a second-1 transmission area of the plurality of second-1 transmission areas may be greater than external light reflectance in the second-2 transmission area, and where the external light reflectance in the second-2 transmission area may be greater than external light reflectance in the second-3 transmission area.

In an embodiment, an opening may be defined in the bank layer and an opening may not be defined in the light-blocking layer, at positions overlapping the plurality of second-1 transmission areas, where an opening may be defined in the light-blocking layer and an opening may not be defined in the bank layer, at positions overlapping the plurality of second-2 transmission areas.

In an embodiment, an opening may not be defined in each of the bank layer and the light-blocking layer, at positions overlapping the plurality of second-3 transmission areas.

In an embodiment, the display device may further include a color filter disposed in the light-blocking layer, where the color filter may be spaced apart from each of the plurality of first transmission areas and the plurality of second transmission areas.

In an embodiment, the emission layer may be spaced apart from each of the plurality of first transmission areas and the plurality of second transmission areas.

In an embodiment of the disclosure, an electronic device includes a display device including a first display area and a second display area, in which a plurality of first transmission areas are included in the first display area, and a plurality of second transmission areas are included in the second display area, and a first component disposed to overlap the plurality of first transmission areas, where the display device includes a substrate, a pixel electrode disposed on the substrate, an emission layer disposed on the pixel electrode, a bank layer covering at least a portion of the pixel electrode, and a light-blocking layer disposed on the bank layer, where an opening is defined in each of the bank layer and the light-blocking layer, at positions overlapping the plurality of first transmission areas, and where an opening is defined in one of the bank layer and the light-blocking layer, at positions overlapping the plurality of second transmission areas.

In an embodiment, the first component may include an illuminance sensor.

In an embodiment, the electronic device may further include a second component disposed to overlap the plurality of second transmission areas, where the second component may include an infrared sensor.

In an embodiment, external light reflectance in a first transmission area of the plurality of first transmission areas of the display device may be greater than external light reflectance in a second transmission area of the plurality of second transmission areas of the display device.

In an embodiment, infrared rays may be transmitted through each of a first transmission area of the plurality of first transmission areas and a second transmission area of the display device of the plurality of second transmission areas.

In an embodiment, a size of the plurality of second transmission areas may gradually decrease with increasing distance from the first display area.

In an embodiment, a number of the plurality of second transmission areas per unit area may gradually decrease with increasing distance from the first display area.

In an embodiment, the second display area may include a second-1 display area, a second-2 display area, and a second-3 display area, which are disposed in order of increasing distance from the first display area, where the plurality of second transmission areas may include a plurality of second-1 transmission areas disposed in the second-1 display area, a plurality of second-2 transmission areas disposed in the second-2 display area, and a plurality of second-3 transmission areas disposed in the second-3 display area, where external light reflectance in a second-1 transmission area of the plurality of second-1 transmission areas of the display device may be greater than external light reflectance in a second-2 transmission area of the plurality of second-2 transmission areas of the display device, and where the external light reflectance in the second-2 transmission area of the display device may be greater than external light reflectance in a second-3 transmission area of the plurality of second-3 transmission areas of the display device.

In an embodiment, an opening may be defined in the bank layer and an opening may not be defined in the light-blocking layer, at positions overlapping the plurality of second-1 transmission areas, where an opening may be defined in the light-blocking layer and an opening may not be defined in the bank layer, at positions overlapping the plurality of second-2 transmission areas.

In an embodiment, an opening may not be defined in each of the bank layer and the light-blocking layer, at positions overlapping the plurality of second-3 transmission areas.

Features and advantages other than the above described things will become apparent from the following detailed description of the disclosure, the accompanying drawings, and claims.

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a schematic perspective view of an embodiment of a display device;

FIG. 2 is a schematic plan view of an embodiment of a display device;

FIG. 3 is a cross-sectional view of an embodiment of a portion of a display device;

FIG. 4 is a schematic plan view of an embodiment of a display device;

FIGS. 5A and 5B are schematic cross-sectional views of an embodiment of a display device;

FIG. 5C is a graph showing an embodiment of transmittance according to the wavelength of a color filter;

FIG. 6 is a schematic plan view of an embodiment of a display device;

FIG. 7 is a schematic cross-sectional view of an embodiment of a display device;

FIGS. 8A and 8B are schematic cross-sectional views of an embodiment of a display device;

FIG. 9 is a schematic cross-sectional view of an embodiment of a display device;

FIGS. 10 and 11 are schematic plan views of an embodiment of a display device;

FIGS. 12A to 12D are schematic plan views of an embodiment of a display device;

FIGS. 13A to 13D are schematic plan views of an embodiment of a display device;

FIGS. 14A to 14D are schematic plan views of an embodiment of a display device;

FIG. 15 is a schematic plan view of an embodiment of a display device;

FIG. 16 is a block diagram of an embodiment of an electronic device; and

FIG. 17 is a schematic view of embodiments of electronic devices.

### DETAILED DESCRIPTION

Reference will now be made in detail to embodiments, illustrative embodiments of which are illustrated in the accompanying drawings, where like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term "and/or" includes any and all combinations of one or more of the associated listed items. Throughout the disclosure, the expression "at least one of a, b, and c" indicates only a, only b, only c, both a and b, both a and c, both b and c, all of a, b, and c, or variations thereof.

As the disclosure allows for various changes and numerous embodiments, illustrative embodiments will be illustrated in the drawings and described in the detailed description. Effects and features of the disclosure, and methods for achieving them will be clarified with reference to embodiments described below with reference to the drawings. However, the disclosure is not limited to embodiments described below and may be implemented in various forms.

Hereinafter, embodiments will be described with reference to the accompanying drawings, where, like or corresponding elements are given like reference numerals when describing with reference to the drawings, and a repeated description thereof is omitted.

In embodiments below, such terms as first and second are not used in a limited meaning and are used for the purpose of distinguishing one element from another.

In embodiments below, the singular expressions include the plural expressions unless the context clearly indicates otherwise.

In embodiments below, the terms such as comprise or have specify the presence of stated features or elements described in the specification but do not preclude possibility of the addition of one or more other features or elements.

In embodiments below, when a portion of a layer, region, or element is referred to as being on another portion, it may include not only a case where the portion of the layer, region, or element is directly on the other portion, but also a case where intervening layers, regions, or elements are disposed therebetween.

Sizes of elements in the drawings may be exaggerated or reduced for convenience of explanation. As an example, the size and thickness of each element shown in the drawings are arbitrarily represented for convenience of description, and thus, the disclosure is not necessarily limited thereto.

In an embodiment below, an x axis, a y axis and a z axis are not limited to three axes of the rectangular coordinate system, and may be interpreted in a broader sense including the same. For example, the x axis, y axis, and z axis may be perpendicular to one another, or may represent different directions that are not perpendicular to one another.

In the case where an illustrative embodiment may be implemented differently, a specific process order may be performed in the order different from the described order. As an example, two processes successively described may be simultaneously performed substantially and performed in the opposite order of the described order.

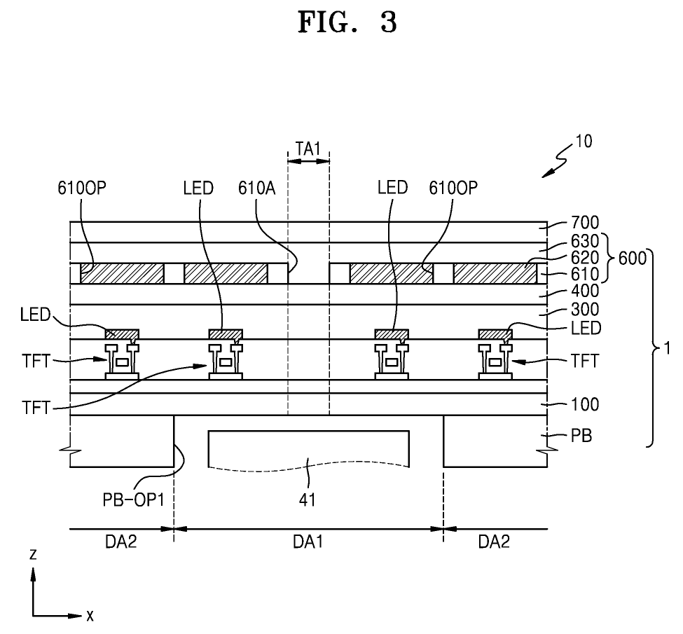

In the specification, "in a plan view" means a plane viewed from a direction perpendicular to a substrate 100 (refer to FIG. 3). That is, "A and B apart from each other in a plan view" means "A and B apart from each other when viewed in a direction perpendicular to the substrate 100 (refer to FIG. 3)."

In the specification, "in a cross-section" means a plane cut in a direction perpendicular to the substrate 100 (refer to FIG. 3). That is, "in a cross-sectional view, A and B apart from each other" means "A and B apart from each other in a plane cut in a direction perpendicular to the substrate 100 (refer to FIG. 3)."

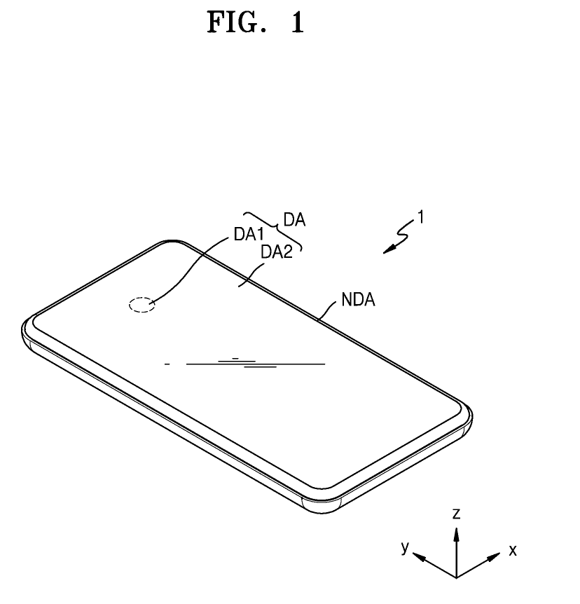

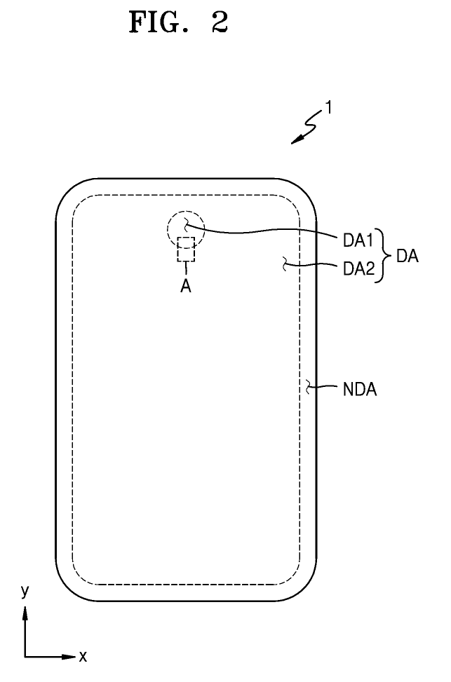

FIG. 1 is a schematic perspective view of an embodiment of a display device 1 in an embodiment, and FIG. 2 is a schematic plan view of an embodiment of the display device 1.

Referring to FIGS. 1 and 2, the display device 1 may include a display area DA and a non-display area NDA outside the display area DA. The display device 1 may display images through an array of a plurality of pixels arranged two-dimensionally in the display area DA.

The non-display area NDA is a region that does not display images and may surround the display area DA entirely. Drivers or the like may be disposed in the non-display area NDA, where the drivers or the like provide electrical signals or power to display elements disposed in the display area DA. A pad may be disposed in the non-display area NDA, where the pad is a region to which electronic elements or a printed circuit board may be electrically connected.

The display area DA may include a first display area DA1 and a second display area DA2. The first display area DA1 may be a region in which a component for adding various functions to the display device 1 is disposed. The first display area DA1 may correspond to a component area.

In an embodiment, as shown in FIGS. 1 and 2, the area of the first display area DA1 may be less than the area of the second display area DA2. Although it is shown in FIGS. 1 and 2 that the first display area DA1 is surrounded by the second display area DA2 entirely, the disclosure is not limited thereto.

FIG. 3 is a cross-sectional view of an embodiment of a portion of the display device 1.

Referring to FIG. 3, an electronic device 10 may include the display device 1 and a component overlapping the display device 1 and disposed on the lower surface of the display device 1. A first component 41 may be disposed in the first display area DA1.

The display device 1 may include the substrate 100, a thin-film transistor TFT disposed on the substrate 100, a display element (e.g., a light-emitting diode LED) electrically connected to the thin-film transistor, an encapsulation layer 300 covering the display element, an input sensing layer 400, an anti-reflection layer 600, and a window 700.

The substrate 100 may include glass or a polymer resin. The substrate 100 including the polymer resin may be flexible, foldable, rollable, or bendable. The substrate 100 may have a multi-layered structure including a layer that includes the polymer resin and an inorganic layer (not shown).

A lower protective film PB may be disposed on the lower surface of the substrate 100. The lower protective film PB may be attached to the lower surface of the substrate 100. An adhesive layer may be disposed between the lower protective film PB and the substrate 100. In an alternative embodiment, the lower protective film PB may be directly formed on the lower surface of the substrate 100. In this case, an adhesive layer is not disposed between the lower protective film PB and the substrate 100.

The lower protective film PB may support and protect the substrate 100. The lower protective film PB may define an opening PB-OP1 corresponding to the first display area DA1. The lower protective film PB may include an organic insulating material such as polyethyleneterephthalate (“PET”) or polyimide (“PI”).

The thin-film transistor TFT and the light-emitting diode LED as a display element electrically connected to the thin-film transistor TFT may be disposed on the upper surface of the substrate 100. The light-emitting diode LED may include an organic light-emitting diode including an organic material. The organic light-emitting diode may emit red, green, or blue light.

The light-emitting diode LED may include an inorganic light-emitting diode including an inorganic material. The inorganic light-emitting diode may include a PN-junction diode including inorganic material semiconductor-based materials. When a forward voltage is applied to a PN-junction diode, holes and electrons are injected, and light of a preset color may be emitted while energy created by recombination of the holes and the electrons is converted to light energy. The inorganic light-emitting diode may have a width of several micrometers to hundreds of micrometers, or several nanometers to hundreds of nanometers. In an embodiment, the light-emitting diode LED may include a light-emitting diode including quantum dots. An emission layer of the light-emitting diode LED may include an organic material, an inorganic material, quantum dots, an organic material and quantum dots, or an inorganic material and quantum dots.

The light-emitting diode LED may be electrically connected to the thin-film transistor TFT disposed therebelow. The thin-film transistor TFT and the light-emitting diode LED may be respectively disposed in the first display area DA1 and the second display area DA2.

A first transmission area TA1 may be disposed in the first display area DA1. As shown in FIG. 3, the first transmission area TA1 between light-emitting diodes LED next (adjacent) to each other may be disposed in the first display area DA1. The first transmission area TA1 is a region through which light emitted from the first component 41 and/or light directed to the first component 41 may pass. Specifically, visible rays and infrared rays may be transmitted through the first transmission area TA1 of the display device 1.

The first component 41 may include a sensor such as a proximity sensor, an illuminance sensor, an iris sensor, and a face recognition sensor, and a camera (or an image sensor). The first component 41 may use light. In an embodiment, the first component 41 may emit and/or receive light in infrared, ultraviolet, and visible light bands. A proximity sensor that uses an infrared ray may detect an object disposed close to the upper surface of the display device 1, and an illuminance sensor may detect brightness of light incident to the upper surface of the display device 1. In addition, an iris sensor may capture a person's iris disposed on the upper surface of the display device 1, and a camera may receive light from an object disposed on the upper surface of the display device 1.

The encapsulation layer 300 may cover the light-emitting diodes LED. The encapsulation layer 300 may include at least one inorganic encapsulation layer and at least one organic encapsulation layer.

The input sensing layer 400 may be disposed on the encapsulation layer 300. The input sensing layer 400 may obtain coordinate information corresponding to an external input, e.g., a touch event of a finger or an object such as a stylus pen. The input sensing layer 400 may include a touch electrode and trace lines connected to the touch electrode. The input sensing layer 400 may sense an external input by a self-capacitance method and/or a mutual capacitance method.

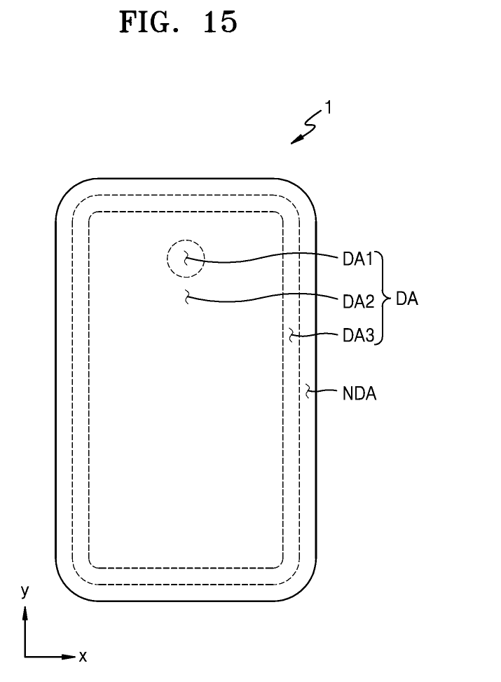

The anti-reflection layer 600 may reduce reflectance of light (external light) incident toward the display panel from the outside. The anti-reflection layer 600 may include a light-blocking layer 610, color filters 620 disposed on the light-blocking layer 610, and an overcoat layer 630. The light-blocking layer 610 may be disposed on a bank layer 123. The light-blocking layer 610 may define openings 610OP overlapping the light-emitting diodes LED in the first to third display areas DA1, DA2, and DA3 (refer to FIG. 15), and the color filters 620 may be respectively disposed in the openings 610OP.

The light-blocking layer 610 may define an opening corresponding to the first transmission area TA1. As shown in FIG. 3, the light-blocking layer 610 may define a second transmission opening 610A corresponding to the first transmission area TA1 provided in the first display area DA1.

The overcoat layer 630 may include a colorless transparent material, and a portion of the overcoat layer 630 may at least partially fill the second transmission opening 610A.

The window 700 is disposed on the anti-reflection layer 600. The window 700 may be coupled to the anti-reflection layer 600 through an adhesive layer such as an optically clear adhesive. The window 700 may include glass or plastic. The glass may include ultra-thin glass. The plastic may include polyethersulfone, polyacrylate, polyetherimide, polyethylene naphthalate, polyethylene terephthalate, polyphenylene sulfide, polyarylate, polyimide, polycarbonate, or cellulose acetate propionate.

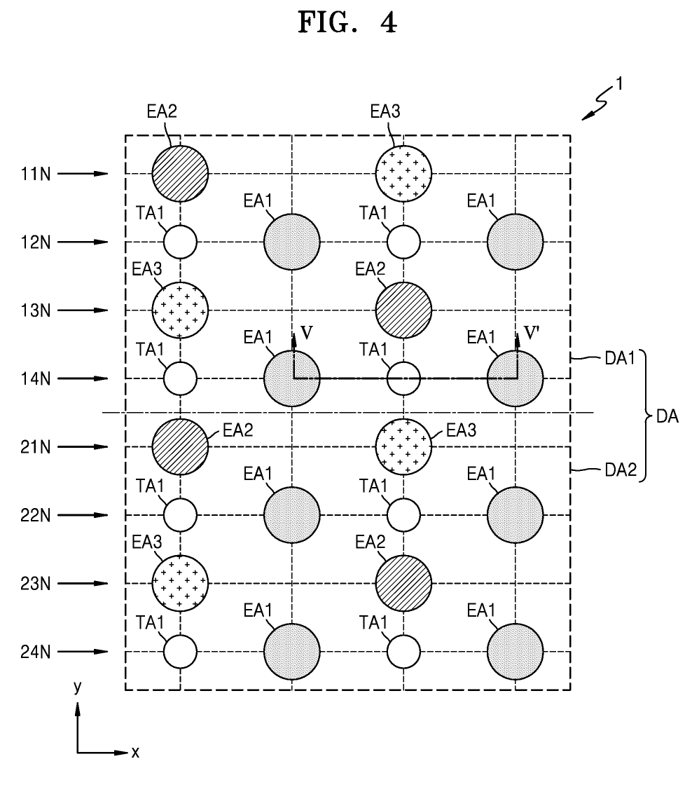

FIG. 4 is a schematic plan view of an embodiment of the display device 1.

Specifically, FIG. 4 is an enlarged view of the display device 1 in a region A of FIG. 2.

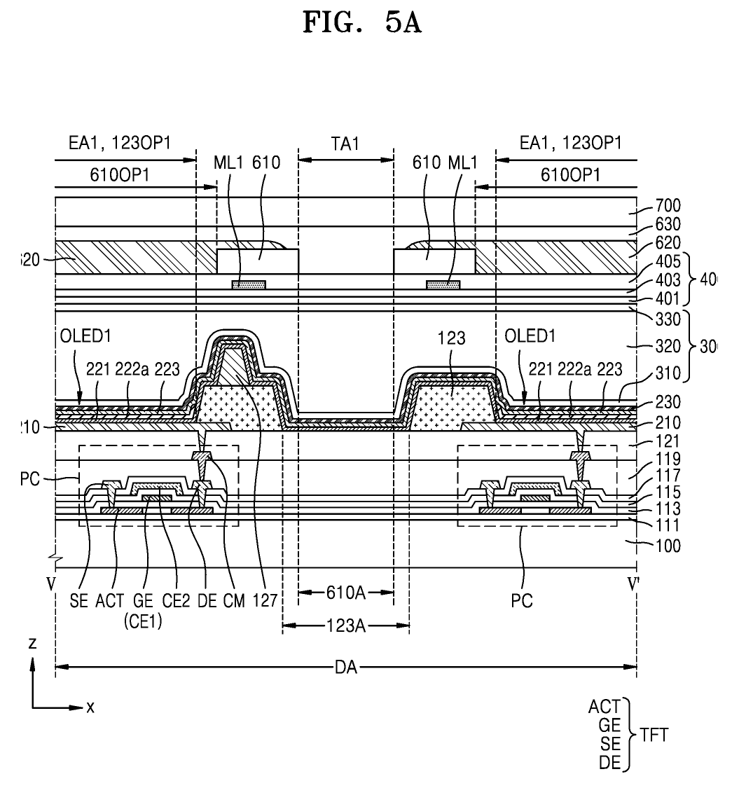

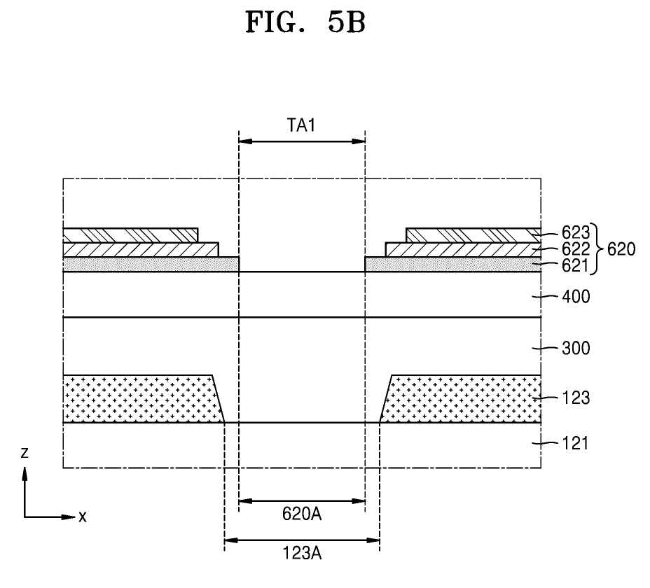

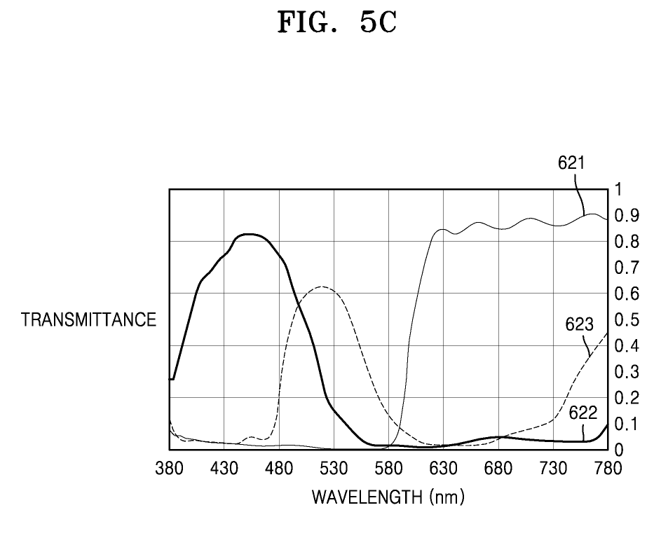

Referring to FIG. 4, first to third emission areas EA1, EA2, and EA3 may be disposed in the display area DA. Specifically, the first to third emission areas EA1, EA2, and EA3 may be disposed in each of the first display area DA1 and the second display area DA2. The first to third emission areas EA1, EA2, and EA3 may emit light of different colors from each other using the light-emitting diodes. One of the first to third emission areas EA1, EA2, and EA3 may correspond to a red emission area, another emission area may correspond to a green emission area, and a remaining (the other) emission area may correspond to a blue emission area. The sizes of the first to third emission areas EA1, EA2, and EA3 may be respectively defined by a plurality of openings defined in the bank layer 123 (refer to FIG. 5A). The first to third emission areas EA1, EA2, and EA3 may be disposed in a pentile^{TM} type, e.g., a diamond pentile^{TM} type.

The first transmission area TA1 may be disposed in the display area DA. Specifically, the first transmission area TA1 may be disposed in each of the first display area DA1 and the second display area DA2. The size of the first transmission area TA1 may be defined by the opening defined in the bank layer 123 (refer to FIG. 5A) and/or the light-blocking layer 610 (refer to FIG. 5A). The opening may be defined in each of the bank layer 123 (refer to FIG. 5A) and the light-blocking layer 610 (refer to FIG. 5A) in positions overlapping the plurality of first transmission areas TA1. Specifically, a first transmission opening 123A (refer to FIG. 5A) may be disposed in the bank layer 123 (refer to FIG. 5A), and a second transmission opening 610A (refer to FIG. 5A) may be disposed in the light-blocking layer 610 (refer to FIG. 5A) in positions overlapping the plurality of first transmission areas TA1.

In the first display area DA1, an eleventh row 11N, a twelfth row 12N, a thirteenth row 13N, and a fourteenth row 14N in a first direction (e.g., an x axis direction and/or a -x axis direction) may be defined. The eleventh row 11N, the twelfth row 12N, the thirteenth row 13N, and the fourteenth row 14N may be sequentially disposed in a second direction (e.g., a y axis direction and/or a -y axis direction) crossing the first direction (e.g., the x axis direction and/or the -x axis direction). A plurality of second emission areas EA2 and a plurality of third emission areas EA3 may be alternately disposed in the eleventh row 11N. A plurality of first transmission areas TA1 and a plurality of first emission areas EA1 may be alternately disposed in the twelfth row 12N. A plurality of third emission areas EA3 and a plurality of second emission areas EA2 may be alternately disposed in the thirteenth row 13N. A plurality of first transmission areas TA1 and a plurality of first emission areas EA1 may be alternately disposed in the fourteenth row 14N.

In the second display area DA2, a 21-st row 21N, a 22-nd row 22N, a 23-rd row 23N, and a 24-th row 24N in the first direction (e.g., the x axis direction and/or the -x axis direction) may be defined. The 21-st row 21N, the 22-nd row 22N, the 23-rd row 23N, and the 24-th row 24N may be sequentially disposed in the second direction (e.g., the y axis direction and/or the -y axis direction). A plurality of second emission areas EA2 and a plurality of third emission areas EA3 may be alternately disposed in the 21-st row 21N. A plurality of first transmission areas TA1 and a plurality of first emission areas EA1 may be alternately disposed in the 22-nd row 22N. A plurality of third emission areas EA3 and a plurality of second emission areas EA2 may be alternately disposed in the 23-rd row 23N. A plurality of first transmission areas TA1 and a plurality of first emission areas EA1 may be alternately disposed in the 24-th row 24N.

In this structure, a plurality of second emission areas EA2, a plurality of first transmission areas TA1, a plurality of third emission areas EA3, and a plurality of first transmission areas TA1 may be alternately disposed in one column in the second direction (e.g., the y axis direction and/or the -y axis direction) of the display area DA. In addition, a plurality of first emission areas EA1 may be disposed apart from each other in one column in the second direction (e.g., the y axis direction and/or the -y axis direction) of the display area DA. With respect to one first transmission area TA1, two first emission areas EA1 next (adjacent) to each other in the first direction (e.g., the x axis direction and/or the -x axis direction) may be disposed. In addition, with respect to one first transmission area TA1, one second emission area EA2 and one third emission area EA3 next (adjacent) to each other in the second direction (e.g., the y axis direction and/or the -y axis direction) may be disposed. That is, one second emission area EA2, one third emission area EA3, and two first emission areas EA1 may surround one first transmission area TA1.

FIGS. 5A and 5B are schematic cross-sectional views of an embodiment of the display device 1, and FIG. 5C is a graph showing an embodiment of a transmittance according to the wavelength of the color filter 620.

Specifically, FIG. 5A is a cross-sectional view of an embodiment of the display device 1 taken along line V-V' of FIGS. 4, and 5B, is an enlarged cross-sectional view of an embodiment of a portion of the display device 1 of FIG. 5A. The embodiment shown in FIG. 5A may be different from the embodiment shown in FIG. 5B.

Referring to FIGS. 4, 5A, and 5B, a first organic light-emitting diode OLED1 may be disposed on the substrate 100. The substrate 100 may include glass or polymer resin, and in the case where the substrate 100 includes polymer resin, the substrate 100 may include a stack structure including a base layer including polymer resin and a barrier layer including an inorganic insulating material.

A buffer layer 111 may be disposed on the substrate 100. The buffer layer 111 may reduce or block penetration of foreign materials, moisture, or external air from below the substrate 100. The buffer layer 111 may include an inorganic insulating material such as silicon oxide, silicon oxynitride, and silicon nitride, and include a single-layered structure or a multi-layered structure including the above materials.

The first organic light-emitting diode OLED1 may be electrically connected to a pixel circuit PC. The pixel circuit PC may include the thin-film transistor TFT and a storage capacitor Cst. The thin-film transistor TFT may include a semiconductor layer ACT, a gate electrode GE, a source electrode SE, and a drain electrode DE, where the gate electrode GE overlaps a channel region of the semiconductor layer ACT, and the source electrode SE and the drain electrode DE are respectively connected to a source region and a drain region of the semiconductor layer ACT. A gate insulating layer 113 may be disposed between the semiconductor layer ACT and the gate electrode GE, and a first inter-insulating layer 115 and a second inter-insulating layer 117 may be disposed between the gate electrode GE and the source electrode SE, or between the gate electrode GE and the drain electrode DE.

The storage capacitor Cst may overlap the thin-film transistor TFT. The storage capacitor Cst may include a lower electrode CE1 and an upper electrode CE2 overlapping each other. In an embodiment, the gate electrode GE of the thin-film transistor TFT may include the lower electrode CE1 of the storage capacitor Cst. The first inter-insulating layer 115 may be disposed between the lower electrode CE1 and the upper electrode CE2.

The semiconductor layer ACT may include polycrystalline silicon. In an embodiment, the semiconductor layer ACT may include amorphous silicon. In an embodiment, the semiconductor layer ACT may include an oxide semiconductor of at least one of indium (In), gallium (Ga), stannum (Sn), zirconium (Zr), vanadium (V), hafnium (Hf), cadmium (Cd), germanium (Ge), chrome (Cr), titanium (Ti), and zinc (Zn). The semiconductor layer ACT may include a channel region, a source region, and a drain region, the source region and the drain region being doped with impurities.

The gate insulating layer 113 may include an inorganic insulating material such as silicon oxide, silicon oxynitride, and silicon nitride, and include a single-layered structure or a multi-layered structure including the above materials.

The gate electrode GE or the lower electrode CE1 may include a conductive material of a low-resistance such as molybdenum (Mo), aluminum (Al), copper (Cu) and/or titanium (Ti), and have a single-layered structure or a multi-layered structure including the above materials.

The first inter-insulating layer 115 may include an inorganic insulating material such as silicon oxide, silicon oxynitride, and silicon nitride, and include a single-layered structure or a multi-layered structure including the above materials.

The upper electrode CE2 may include aluminum (Al), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), and/or copper (Cu), and include a single layer or a multi-layer including the above materials.

The second inter-insulating layer 117 may include an inorganic insulating material such as silicon oxide, silicon oxynitride, and silicon nitride, and include a single-layered structure or a multi-layered structure including the above materials.

The source electrode SE and/or the drain electrode DE may include aluminum (Al), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), and/or copper (Cu), and include a single layer or a multi-layer including the above materials. In an embodiment, the source electrode SE and/or the drain electrode DE may each have a three-layered structure of a titanium layer/aluminum layer/titanium layer.

A first organic insulating layer 119 may be disposed on the thin-film transistor TFT. The thin-film transistor TFT may be electrically connected to a pixel electrode 210 of an organic light-emitting diode disposed on the substrate 100 through a connection electrode CM disposed on the first organic insulating layer 119. The connection electrode CM may be connected to the thin-film transistor TFT through a contact hole of the first organic insulating layer 119, and the pixel electrode 210 may be connected to the connection electrode CM through a contact hole of a second organic insulating layer 121.

The first organic insulating layer 119 and/or the second organic insulating layer 121 may each include an organic insulating material such as benzocyclobutene (“BCB”), polyimide, or hexamethyldisiloxane (“HMDSO”). In an embodiment, the connection electrode CM and the second organic insulating layer 121 may be omitted. In this case, the pixel electrode 210 may be in direct contact with the thin-film transistor TFT through a contact hole of the first organic insulating layer 119.

The first organic light-emitting diode OLED1 may have an overlapping structure of the pixel electrode 210, an emission layer 222a, and an opposite electrode 230. The emission layer 222a may be disposed on the pixel electrode 210. The emission layer 222a (also referred to as a first emission layer, hereinafter) may be spaced apart from the first transmission area TA1.

A first functional layer 221 and/or a second functional layer 223 may be included between the pixel electrode 210 and the opposite electrode 230.

The pixel electrode 210 may be disposed on the second organic insulating layer 121. The pixel electrode 210 may include a reflective layer including silver (Ag), magnesium (Mg), aluminum (Al), platinum (Pt), palladium (Pd), gold (Au), nickel (Ni), neodymium (Nd), iridium (Ir), chrome (Cr), or any combinations thereof. The pixel electrode 210 may include a reflective layer and a transparent conductive layer, where the reflective layer includes the above materials, and the transparent conductive layer is disposed on/under the reflective layer. The transparent conductive layer may include indium tin oxide (“ITO”), indium zinc oxide (“IZO”), zinc oxide (ZnO), indium oxide (In₂O₃), indium gallium oxide (“IGO”), or aluminum zinc oxide (“AZO”). In an embodiment, the pixel electrode 210 may have a three-layered structure of ITO layer/Ag layer/ITO layer.

The bank layer 123 may include a light-blocking material. The bank layer 123 may cover at least a portion of the pixel electrode 210. The bank layer 123 may have, e.g., a black color. In an embodiment, the bank layer 123 may include a polyimide (“PI”)-based binder and pigment in which red, green, and blue are mixed. In an alternative embodiment, the bank layer 123 may include a carbo-based binder resin and a combination of lactam black pigment and blue pigment. In an alternative embodiment, the bank layer 123 may include carbon black. The bank layer 123 may prevent reflection of external light in cooperation of the anti-reflection layer 600 described below and may improve contrast of a display panel.

A spacer 127 may be disposed on the bank layer 123. The spacer 127 may include a material different from that of the bank layer 123. In an embodiment, the bank layer 123 may include a different material, such as a negative photosensitive material while the spacer 127 may include a positive photosensitive material, and each may be formed through a separate mask process.

The first emission layer 222a may be disposed to correspond to a first bank opening 123OP1 of the bank layer 123 and may overlap the pixel electrode 210. The first emission layer 222a may include a polymer organic material or a low-molecular weight organic material emitting light having a preset color and may emit light. The first functional layer 221 and the second functional layer 223 may be respectively formed under and on the first emission layer 222a.

The first functional layer 221 may include a hole transport layer (“HTL”) and/or a hole injection layer (“HIL”). The second functional layer 223 may include an electron transport layer (“ETL”) and/or an electron injection layer (“EIL”). Unlike the emission layer 222, the first functional layer 221 and/or the second functional layer 223 may be formed over the substrate 100 entirely. In other words, the first functional layer 221 and/or the second functional layer 223 may cover the first display area DA1 and the second display area DA2.

The opposite electrode 230 may include a material having a relatively high work function. In an embodiment, the opposite electrode 230 may include a light transmissive thin layer including silver (Ag) and magnesium (Mg).

The encapsulation layer 300 may cover the first emission area EA1, e.g., the first organic light-emitting diode OLED1. In an embodiment, the encapsulation layer 300 may include a first inorganic encapsulation layer 310, a second inorganic encapsulation layer 330, and an organic encapsulation layer 320 therebetween.

The first and second inorganic encapsulation layers 310 and 330 may each include at least one inorganic insulating material. The inorganic insulating material may include aluminum oxide, titanium oxide, tantalum oxide, hafnium oxide, zinc oxide, silicon oxide, silicon nitride, and/or silicon oxynitride.

The organic encapsulation layer 320 may include a polymer-based material. The polymer-based material may include an acryl-based resin, an epoxy-based resin, polyimide, and polyethylene. In an embodiment, the organic encapsulation layer 320 may include an acryl-based resin, such as polymethyl methacrylate or polyacrylic acid. The organic encapsulation layer 320 may be formed by curing a monomer or coating a polymer.

The input sensing layer 400 may include a first touch insulating layer 401 on the encapsulation layer 300, a second touch insulating layer 403 on the first touch insulating layer 401, and a third touch insulating layer 405 on the second touch insulating layer 403. The input sensing layer 400 may include a touch electrode, and the touch electrode may include a conductive line disposed on the second touch insulating layer 403 and under the third touch insulating layer 405. In this regard, in an embodiment, FIG. 5A shows a first conductive line ML1.

The conductive line, e.g., the first conductive line ML1 of FIG. 5A may include molybdenum (Mo), mendelevium (Mb), silver (Ag), titanium (Ti), copper (Cu), aluminum (Al), and any alloys thereof. The first conductive line ML1 may be covered by the light-blocking layer 610 having a greater width than that of the first conductive line ML1.

The bank layer 123 defines first bank openings 123OP1 defining the first emission area EA1, and may define a first transmission opening 123A defined between two first bank openings 123OP1 and corresponding to the first transmission area TA1.

The first conductive line ML1 may be disposed to overlap a material portion of the bank layer 123 not to overlap the first bank opening 123OP1 of the bank layer 123. The first conductive line ML1 may overlap the material portion of the bank layer 123 and overlap the light-blocking layer 610.

The light-blocking layer 610 serving as an external light prevention layer defines a first light-blocking opening 610OP1 overlapping each first emission area EA1, and may define a second transmission opening 610A defined between first light-blocking openings 610OP1 next (adjacent) to each other and corresponding to the first transmission area TA1. The second transmission opening 610A may be defined by the lateral wall of the light-blocking layer 610. The second transmission opening 610A may be at least partially filled with a portion of the overcoat layer 630.

The size (or width) of the second transmission opening 610A of the light-blocking layer 610 may be different from the size (or width) of the first transmission opening 123A of the bank layer 123. In an embodiment, as shown in FIG. 5A, the size (or width) of the second transmission opening 610A of the light-blocking layer 610 may be formed less than the size (or width) of the first transmission opening 123A of the bank layer 123, and in this case, the size (or width) of the first transmission area TA1 may be defined by the second transmission opening 610A of the light-blocking layer 610 which is relatively small. Unlike FIG. 5A, the size (or width) of the second transmission opening 610A of the light-blocking layer 610 may be formed greater than the size (or width) of the first transmission opening 123A of the bank layer 123, and in this case, the size (or width) of the first transmission area TA1 may be defined by the first transmission opening 123A of the bank layer 123 which is relatively small.

The color filter 620 may be disposed in the first light-blocking opening 610OP1 of the light-blocking layer 610. The color filter 620 may be spaced apart from a plurality of first transmission areas TA1. The color filter 620 may have a color corresponding to light emitted from the first emission area EA1. In an embodiment, in the case where green light is emitted from the first emission area EA1, the color filter 620 is a green color filter.

The overcoat layer 630 may be disposed on the light-blocking layer 610 and the color filters. The overcoat layer 630 is a colorless light-transmissive layer that does not have a color in the visible light band and may planarize the upper surface of the light-blocking layer 610 and the upper surface of the color filter 620. The overcoat layer 630 may include a colorless light transmissive organic material such as an acryl-based resin and be covered by the window 700.

Light incident into the inside of the display device 1 from the outside of the display device 1 may be reflected by the opposite electrode and be emitted back to the outside of the display device 1. Because a plurality of first transmission areas TA1 are disposed in each of the first display area DA1 and the second display area DA2, a difference between an external light reflectance in the first display area DA1 and an external light reflectance in the second display area DA2 may be reduced. Accordingly, a phenomenon in which a boundary between the first display area DA1 and the second display area DA2 is visible due to a sharp difference in external light reflectance between the first display area DA1 and the second display area DA2 may be reduced.

FIG. 5A shows a region corresponding to two first emission areas EA1 and one first transmission area TA1 disposed next (adjacent) to each other in the first direction (e.g., the x axis direction and/or the -x axis direction) in the first display area DA1. However, this is just an example for convenience of description, and this is equally applicable to not only the first display area DA1 but also the second display area DA2, and equally applicable to not only the first emission area EA1 but also the second emission area EA2 and the third emission area EA3.

According to the embodiment shown in FIG. 5B, unlike the embodiment shown in FIG. 5A, the light-blocking layer 610 defining the second transmission opening 610A is not disposed in the display device 1, and the plurality of color filters 620 defining the third transmission opening 620A may be disposed in the display device 1. The third transmission opening 620A may correspond to the first transmission area TA1. Instead of the light-blocking layer 610, a first color filter 621, a second color filter 622, and a third color filter 623 may be sequentially stacked at the position where the light-blocking layer 610 is disposed. In an embodiment, the first color filter 621 may have a red color, the second color filter 622 may have a blue color, and the third color filter 623 may have a green color. In an embodiment, the first color filter 621 may have a blue color, the second color filter 622 may have a red color, and the third color filter 623 may have a green color. In an embodiment, the end of the first color filter 621 may be disposed further inward than the end of the bank layer 123. The end of the second color filter 622 may be disposed further outward than the end of the bank layer 123 or disposed at the same position as the end of the bank layer 123. The end of the third color filter 623 may be disposed further outward than the end of the bank layer 123 or disposed at the same position as the end of the bank layer 123. In this structure, the bank layer 123 may be screened by the first color filter 621 and the second color filter 622. As shown in FIG. 5C, because, when the second color filter (e.g., blue color filter) 622 and the first color filter (e.g., red color filter) 621 overlap each other, most of light may be blocked, the structure of the overlapping color filters 620 may serve as the light-blocking layer 610. That is, the structure of the overlapping color filters 620 may serve as an external light prevention layer.

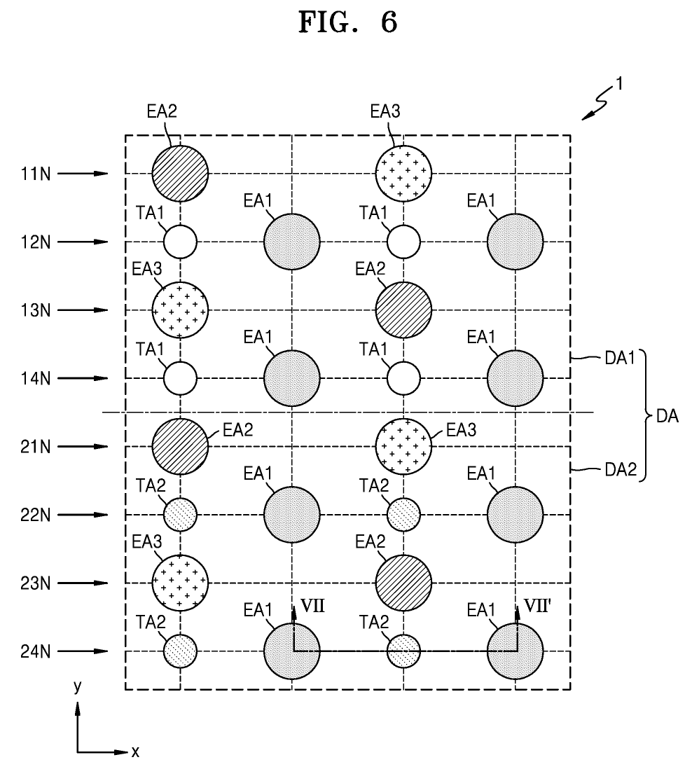

FIG. 6 is a schematic plan view of an embodiment of the display device 1.

Specifically, FIG. 6 is an enlarged view of an embodiment of the display device 1 in a region A of FIG. 2.

Referring to FIG. 6, the first to third emission areas EA1, EA2, and EA3 may be disposed in the display area DA. Specifically, the first to third emission areas EA1, EA2, and EA3 may be disposed in each of the first display area DA1 and the second display area DA2. The first transmission area TA1 may be disposed in the first display area DA1. The second transmission area TA2 may be disposed in the second display area DA2.

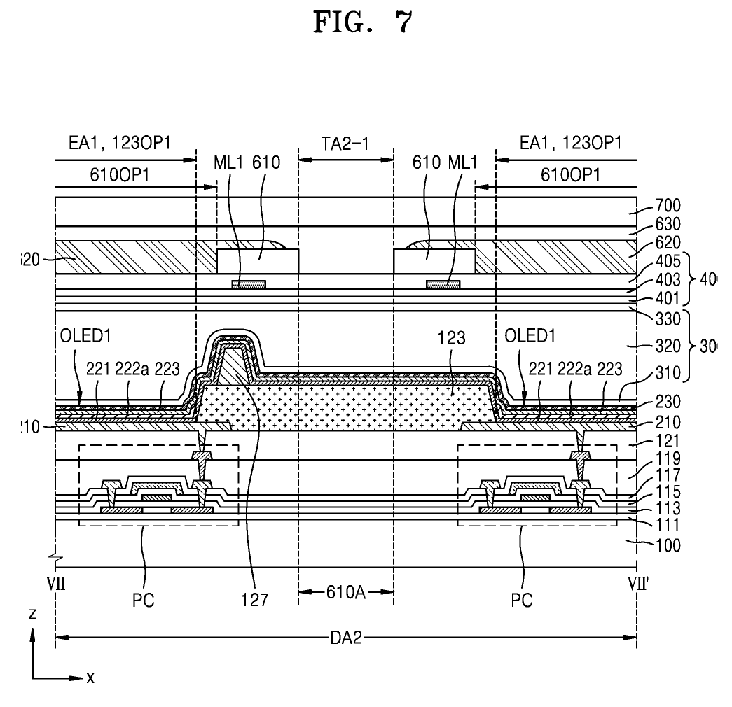

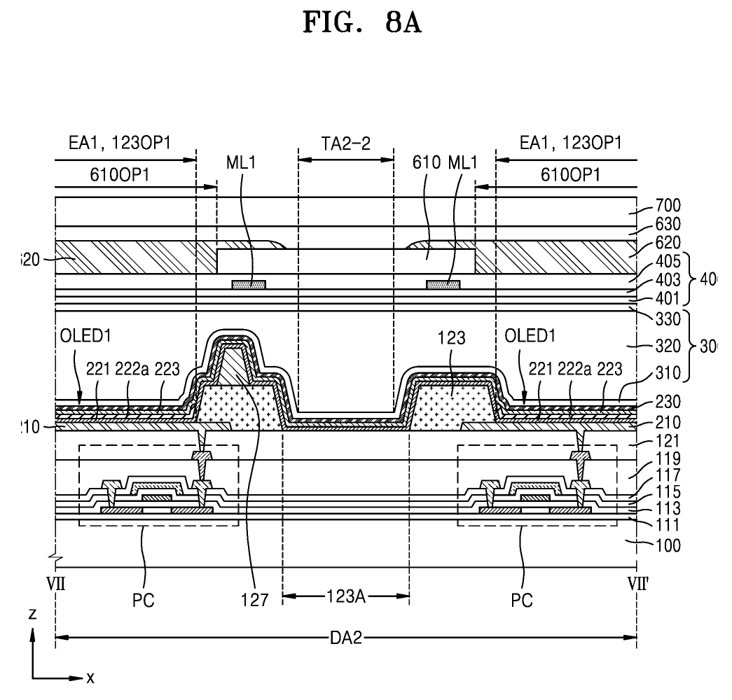

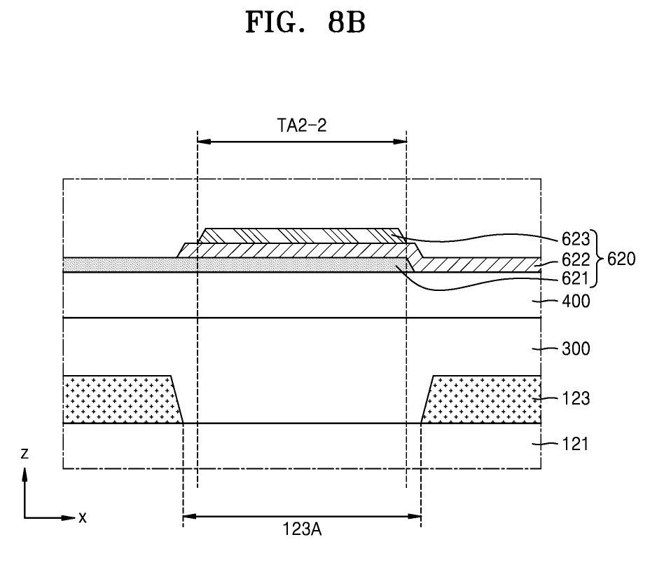

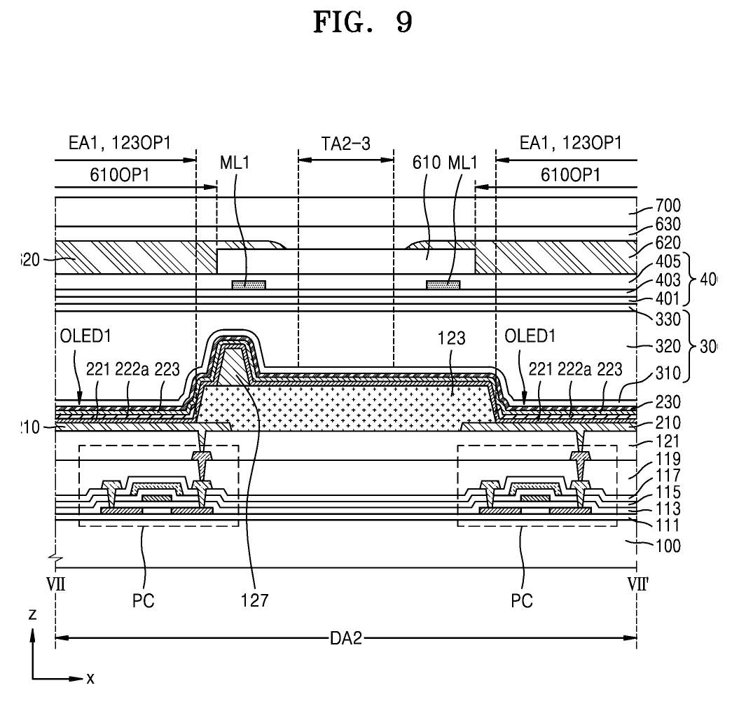

The opening may be defined in one of the bank layer 123 (refer to FIG. 7) and the light-blocking layer 610 (refer to FIG. 7) in positions overlapping the plurality of second transmission areas TA2. In an embodiment, in positions overlapping a plurality of second-1 transmission areas TA2-1 (refer to FIG. 7), an opening (specifically, the second transmission opening 610A (refer to FIG. 7)) may be defined in the light-blocking layer 610 (refer to FIG. 7), and an opening may not be defined in the bank layer 123 (refer to FIG. 7). In an embodiment, in positions overlapping a plurality of second-2 transmission areas TA2-2 (refer to FIG. 8A), an opening (specifically, the first transmission opening 123A (refer to FIG. 8A) may be defined in the bank layer 123 (refer to FIG. 8A), and an opening may not be defined in the light-blocking layer 610 (refer to FIG. 8A). In an alternative embodiment, in positions overlapping a plurality of second-3 transmission areas TA2-3 (refer to FIG. 9), an opening may not be defined in each of the bank layer 123 (refer to FIG. 9) and the light-blocking layer 610 (refer to FIG. 9).

In the first display area DA1, the eleventh row 11N, the twelfth row 12N, the thirteenth row 13N, and the fourteenth row 14N in the first direction (e.g., the x axis direction and/or the -x axis direction) may be defined. The eleventh row 11N, the twelfth row 12N, the thirteenth row 13N, and the fourteenth row 14N may be sequentially disposed in the second direction (e.g., the y axis direction and/or the -y axis direction). The plurality of second emission areas EA2 and the plurality of third emission areas EA3 may be alternately disposed in the eleventh row 11N. The plurality of first transmission areas TA1 and the plurality of first emission areas EA1 may be alternately disposed in the twelfth row 12N. The plurality of third emission areas EA3 and the plurality of second emission areas EA2 may be alternately disposed in the thirteenth row 13N. The plurality of first transmission areas TA1 and the plurality of first emission areas EA1 may be alternately disposed in the fourteenth row 14N.

In the second display area DA2, the 21-st row 21N, the 22-nd row 22N, the 23-rd row 23N, and the 24-th row 24N in the first direction (e.g., the x axis direction and/or the -x axis direction) may be defined. The 21-st row 21N, the 22-nd row 22N, the 23-rd row 23N, and the 24-th row 24N may be sequentially disposed in the second direction (e.g., the y axis direction and/or the -y axis direction). The plurality of second emission areas EA2 and the plurality of third emission areas EA3 may be alternately disposed in the 21-st row 21N. The plurality of second transmission areas TA2 and a plurality of first emission areas EA1 may be alternately disposed in the 22-nd row 22N. The plurality of third emission areas EA3 and the plurality of second emission areas EA2 may be alternately disposed in the 23-rd row 23N. The plurality of second transmission areas TA2 and the plurality of first emission areas EA1 may be alternately disposed in the 24-th row 24N.

In this structure, the plurality of second emission areas EA2, the plurality of first transmission areas TA1, the plurality of third emission areas EA3, and the plurality of first transmission areas TA1 may be alternately disposed in one column in the second direction (e.g., the y axis direction and/or the -y axis direction) of the first display area DA1. The plurality of second emission areas EA2, the plurality of second transmission areas TA2, the plurality of third emission areas EA3, and the plurality of second transmission areas TA2 may be alternately disposed in one column in the second direction (e.g., the y axis direction and/or the -y axis direction) of the second display area DA2. In addition, the plurality of first emission areas EA1 may be disposed apart from each other in one column in the second direction (e.g., the y axis direction and/or the -y axis direction) of the display area DA.

In the first display area DA1, with respect to one first transmission area TA1, two first emission areas EA1 next (adjacent) to each other in the first direction (e.g., the x axis direction and/or the -x axis direction) may be disposed. In addition, in the first display area DA1, with respect to one first transmission area TA1, one second emission area EA2 and one third emission area EA3 next (adjacent) to each other in the second direction (e.g., the y axis direction and/or the -y axis direction) may be disposed. That is, in the first display area DA1, one second emission area EA2, one third emission area EA3, and two first emission areas EA1 may surround one first transmission area TA1.

In the second display area DA2, with respect to one second transmission area TA2, two first emission areas EA1 next (adjacent) to each other in the first direction (e.g., the x axis direction and/or the -x axis direction) may be disposed. In addition, in the second display area DA2, with respect to one second transmission area TA2, one second emission area EA2 and one third emission area EA3 next (adjacent) to each other in the second direction (e.g., the y axis direction and/or the -y axis direction) may be disposed. That is, in the second display area DA2, one second emission area EA2, one third emission area EA3, and two first emission areas EA1 may surround one second transmission area TA2.

FIG. 7 is a schematic cross-sectional view of an embodiment of the display device 1.

Specifically, FIG. 7 is a cross-sectional view of the display device 1 taken along line VII-VII' of FIG. 6.

In FIG. 7, the same reference numerals as those of FIG. 5A denote the same members, and thus, repeated descriptions thereof are omitted.

Referring to FIGS. 6 and 7, the first transmission area TA1 may be disposed in the first display area DA1, and the second transmission area TA2 may be disposed in the second display area DA2. Because specific description of the first transmission area TA1 disposed in the first display area DA1 is described above with reference to FIG. 5A, description thereof is omitted. The second transmission area TA2 may include a second-1 transmission area TA2-1.

In the second display area DA2, the bank layer 123 may define first bank openings 123OP1 defining the first emission area EA1, and an opening may not be defined between two first bank openings 123OP1. That is, the first transmission opening 123A (refer to FIG. 5A) may not be defined in the second-1 transmission area TA2-1. A material portion of the bank layer 123 may be disposed in a position overlapping the second-1 transmission area TA2-1 in the second display area DA2.

The first light-emitting diode OLED1 may have an overlapping structure of the pixel electrode 210, the emission layer 222a, and the opposite electrode 230. The emission layer 222a may be disposed on the pixel electrode 210. The emission area 222a may be spaced apart from the second transmission area TA2. Specifically, the emission area 222a (also referred to as a first emission area, hereinafter) may be spaced apart from the second-1 transmission area TA2-1.

In the second display area DA2, the light-blocking layer 610 defines the first light-blocking opening 610OP1 overlapping each first emission area EA1, and may include a second transmission opening 610A defined between first light-blocking openings 610OP1 next (adjacent) to each other and corresponding to the second-1 transmission area TA2-1. The second transmission opening 610A may be defined by the lateral wall of the light-blocking layer 610. The second transmission opening 610A may be at least partially filled with a portion of the overcoat layer 630. The size (or width) of the second-1 transmission area TA2-1 may be defined by the second transmission opening 610A of the light-blocking layer 610.

The color filter 620 may be disposed in the first light-blocking opening 610OP1 of the light-blocking layer 610. The color filter 620 may be spaced apart from the plurality of first transmission areas TA1. Specifically, the color filter 620 may be spaced apart from the plurality of second-1 transmission areas TA2-1.

In an embodiment, although not shown in FIG. 7, in a position overlapping the second-1 transmission area TA2-1, a separate conductive layer may be disposed between the bank layer 123 and the substrate 100. Because the separate conductive layer overlaps the bank layer 123, the separate conductive layer may not be viewed in the outside. In an embodiment, in a position overlapping the second-1 transmission area TA2-1, a separate signal line may be disposed between the first organic insulating layer 119 and the second organic insulating layer 121. Accordingly, the wiring integration of the lower structure of the first organic light-emitting diode OLED1 may be improved.

In an embodiment, as described above with reference to FIGS. 5B and 5C, the light-blocking layer 610 defining the second transmission opening 610A is not disposed in the display device1, and the plurality of color filters 620 (refer to FIG. 5B) defining the third transmission opening 620A (refer to FIG. 5B) may be disposed in the display device 1. In the position in which the light-blocking layer 610, the first color filter 621 (refer to FIG. 5B), the second color filter 622 (refer to FIG. 5B), and the third color filter 623 (refer to FIG. 5B) may be sequentially stacked instead of the light-blocking layer 610. Because the structure in which the plurality of color filters 620 (refer to FIG. 5B) are stacked is described above with reference to FIGS. 5B and 5C, predetermined description thereof is omitted.

FIGS. 8A and 8B are schematic cross-sectional views of an embodiment of the display device 1.

Specifically, FIG. 8A is a cross-sectional view of the display device 1 taken along line VII-VII' of FIGS. 6, and 8B, is an enlarged cross-sectional view of an embodiment of a portion of the display device 1 of FIG. 8A. The embodiment shown in FIG. 8A may be different from the embodiment shown in FIG. 8B.

In FIGS. 8A and 8B, the same reference numerals as those of FIGS. 5A and 5B denote the same members, and thus, repeated descriptions thereof are omitted.

Referring to FIGS. 6, 8A, and 8B, the first transmission area TA1 may be disposed in the first display area DA1, and the second transmission area TA2 may be disposed in the second display area DA2. Because specific description of the first transmission area TA1 disposed in the first display area DA1 is described above with reference to FIG. 5A, description thereof is omitted. The second transmission area TA2 may include the second-2 transmission area TA2-2.

In the second display area DA2, the bank layer 123 defines the first bank openings 123OP1 defining the first emission area EA1, and may define the first transmission opening 123A defined between two first bank openings 123OP1 and corresponding to the second-2 transmission area TA2-2.

In the second display area DA2, the light-blocking layer 610 may define the first light-blocking opening 610OP1 overlapping each first emission area EA1, and an opening may not be defined between first light-blocking openings 610OP1 next (adjacent) to each other. That is, the second transmission opening 610A (refer to FIG. 5A) may not be defined in the second-2 transmission area TA2-2. A material portion of the light-blocking layer 610 may be disposed in a position overlapping the second-2 transmission area TA2-2 in the second display area DA2.

In an embodiment, although not shown in FIG. 8A, in a position overlapping the second-2 transmission area TA2-2, a separate conductive layer may be disposed between the bank layer 123 and the substrate 100. Because the separate conductive layer overlaps the light-blocking layer 610, the separate conductive layer may not be viewed in the outside. In an embodiment, in a position overlapping the second-2 transmission area TA2-2, a separate signal line may be disposed between the first organic insulating layer 119 and the second organic insulating layer 121. Accordingly, the wiring integration of the lower structure of the first organic light-emitting diode OLED1 may be improved.

According to the embodiment shown in FIG. 8B, unlike the embodiment shown in FIG. 8A, the light-blocking layer 610 is not disposed in the display device 1, and the plurality of color filters 620 may be disposed in the display device 1. Instead of the light-blocking layer 610, the first color filter 621, the second color filter 622, and the third color filter 623 may be sequentially stacked at the position where the light-blocking layer 610 is disposed. In an embodiment, the first color filter 621 may have a red color, the second color filter 622 may have a blue color, and the third color filter 623 may have a green color. The structure of the first color filter 621, the second color filter 622, and the third color filter 623 may correspond to the second-2 transmission area TA2-2. Accordingly, visible light rays may not pass through the second-2 transmission area TA2-2.

FIG. 9 is a schematic cross-sectional view of an embodiment of the display device 1.

Specifically, FIG. 9 is a cross-sectional view of the display device 1 taken along line VII-VII' of FIG. 6.

In FIG. 9, the same reference numerals as those of FIG. 5A denote the same members, and thus, repeated descriptions thereof are omitted.

Referring to FIGS. 6 and 9, the first transmission area TA1 may be disposed in the first display area DA1, and the second transmission area TA2 may be disposed in the second display area DA2. Because predetermined description of the first transmission area TA1 disposed in the first display area DA1 is described with reference to FIG. 5A, description thereof is omitted. The second transmission area TA2 may include the second-3 transmission area TA2-3.

In the second display area DA2, the bank layer 123 may define first bank openings 123OP1 defining the first emission area EA1, and an opening may not be defined between two first bank openings 123OP1. That is, the first transmission opening 123A (refer to FIG. 5A) may not be defined in the second-3 transmission area TA2-3. A material portion of the bank layer 123 may be disposed in a position overlapping the second-3 transmission area TA2-3 in the second display area DA2.

In the second display area DA2, the light-blocking layer 610 may define the first light-blocking opening 610OP1 overlapping each first emission area EA1, and an opening may not be defined between first light-blocking openings 610OP1 next (adjacent) to each other. That is, the second transmission opening 610A (refer to FIG. 5A) may not be defined in the second-3 transmission area TA2-3. A material portion of the light-blocking layer 610 may be disposed in a position overlapping the second-3 transmission area TA2-3 in the second display area DA2.

In an embodiment, although not shown in FIG. 9, in a position overlapping the second-3 transmission area TA2-3, a separate conductive layer may be disposed between the bank layer 123 and the substrate 100. Because the separate conductive layer overlaps the bank layer 123 and the light-blocking layer 610, the separate conductive layer may not be viewed in the outside. In an embodiment, in a position overlapping the second-3 transmission area TA2-3, a separate signal line may be disposed between the first organic insulating layer 119 and the second organic insulating layer 121. Accordingly, the wiring integration of the lower structure of the first organic light-emitting diode OLED1 may be improved.

FIGS. 7 to 9 shows a region corresponding to two first emission areas EA1 and one first transmission area TA1 disposed next (adjacent) to each other in the first direction (e.g., the x axis direction and/or the -x axis direction) in the second display area DA2. However, this is just an example for convenience of description, this is equally applicable to the first emission area EA1 disposed in the second display area DA2 but also the second emission area EA2 and the third emission area EA3 disposed in the second display area DA2.

Because the plurality of second transmission areas TA2 are disposed in the second display area DA2, a difference between external light reflectance in the first display area DA1 and external light reflectance in the second display area DA2 may be reduced. Accordingly, a phenomenon in which a boundary between the first display area DA1 and the second display area DA2 is visible due to a sharp difference in external light reflectance between the first display area DA1 and the second display area DA2 may be reduced.

Referring to FIGS. 6 to 9, in positions overlapping the plurality of first transmission areas TA1, an opening may be defined in each of the bank layer 123 and the light-blocking layer 610, and in positions overlapping the plurality of second transmission areas TA2, an opening may be defined in one of the bank layer 123 and the light-blocking layer 610. Accordingly, a transmittance of visible light rays in the first transmission area TA1 may be greater than a transmittance of visible light rays in the second transmission area TA2. Specifically, visible light rays may pass through the first transmission area TA1, but visible light rays may not substantially pass through the second transmission area TA2. However, infrared rays may pass through each of the first transmission area TA1 and the second transmission area TA2.

In an embodiment, a second component may be disposed to overlap the second transmission area TA2 in the second display area DA2. The second component may be disposed on the lower surface of the display device 1. Because the transmittance of visible light rays is relatively low in the second transmission area TA2, the second component may include an infrared sensor. In an embodiment, the second component includes a proximity sensor that uses infrared rays, and may detect an object disposed close to the upper surface of the display device 1. In an embodiment, the second component may include an infrared fingerprint sensor.

In an embodiment, as described with reference to FIG. 8B, the light-blocking layer 610 is not disposed in the display device 1, and the plurality of color filters 620 (refer to FIG. 8B) may be disposed in the display device 1. In the position in which the light-blocking layer 610, the first color filter 621 (refer to FIG. 8B), the second color filter 622 (refer to FIG. 8B), and the third color filter 623 (refer to FIG. 8B) may be sequentially stacked instead of the light-blocking layer 610. Because the structure in which the plurality of color filters 620 (refer to FIG. 8B) are stacked is described above with reference to FIG. 8B, predetermined description thereof is omitted.

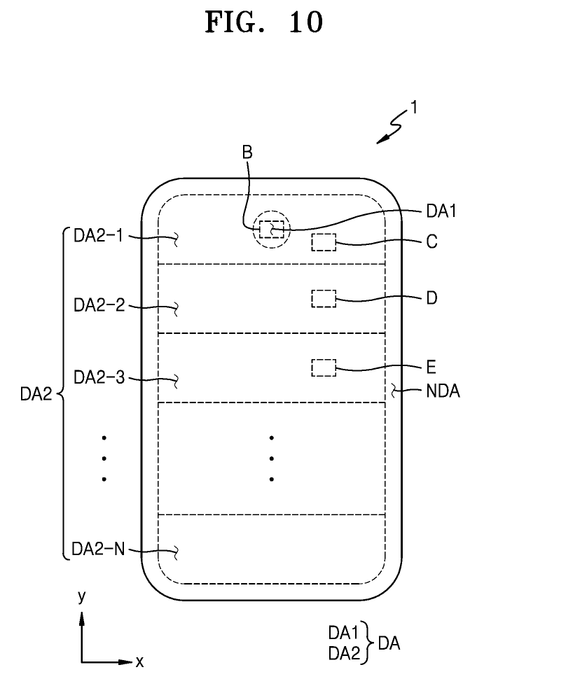

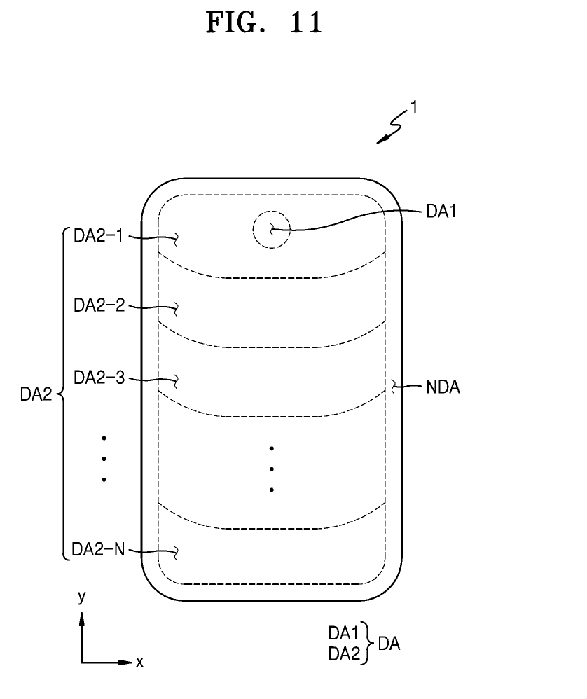

FIGS. 10 and 11 are schematic plan views of an embodiment of the display device 1.

Referring to FIGS. 10 and 11, the display device 1 may include the display area DA and the non-display area NDA outside the display area DA.

The display area DA may include a first display area DA1 and a second display area DA2. The first display area DA1 may be a region in which a component for adding various functions to the display device 1 is disposed. The first display area DA1 may correspond to a component area.

In an embodiment, as shown in FIGS. 10 and 11, the area of the first display area DA1 may be less than the area of the second display area DA2. Although it is shown in FIGS. 1 and 10 that the first display area DA1 is surrounded by the second display area DA2 entirely, the disclosure is not limited thereto.

The second display area DA2 may be divided into a plurality of regions. In an embodiment, the second display area DA2 may include a second-1 display area DA2-1, a second-2 display area DA2-2, a second-3 display area DA2-3, and a second-N display area DA2-N which are disposed sequentially away from the first display area DA1. In an embodiment, the second-1 display area DA2-1 may contact the first display area DA1 and the second-2 display area DA2-2. The second-2 display area DA2-2 may contact the second-1 display area DA2-1 and the second-3 display area DA2-3. The second-N display area DA2-N may be spaced apart from the second-3 display area DA2-3, and a plurality of regions may be disposed between the second-3 display area DA2-3 and the second-N display area DA2-N.

The planar shapes of the second-1 display area DA2-1, the second-2 display area DA2-2, the second-3 display area DA2-3, and the second-N display area DA2-N may be various. In an embodiment, as shown in FIG. 10, each of the second-1 display area DA2-1, the second-2 display area DA2-2, the second-3 display area DA2-3, and the second-N display area DA2-N may be provided in a quadrangular shape, e.g., rectangular shape. In an alternative embodiment, as shown in FIG. 11, each of the second-1 display area DA2-1, the second-2 display area DA2-2, the second-3 display area DA2-3, and the second-N display area DA2-N may be provided in a shape including a curve.

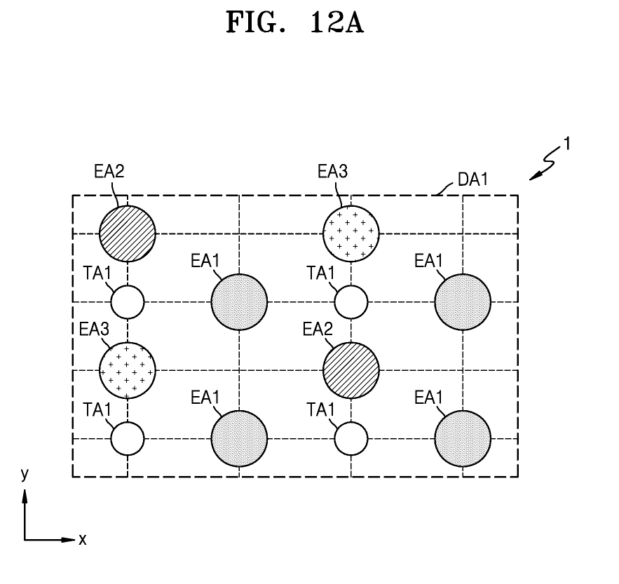

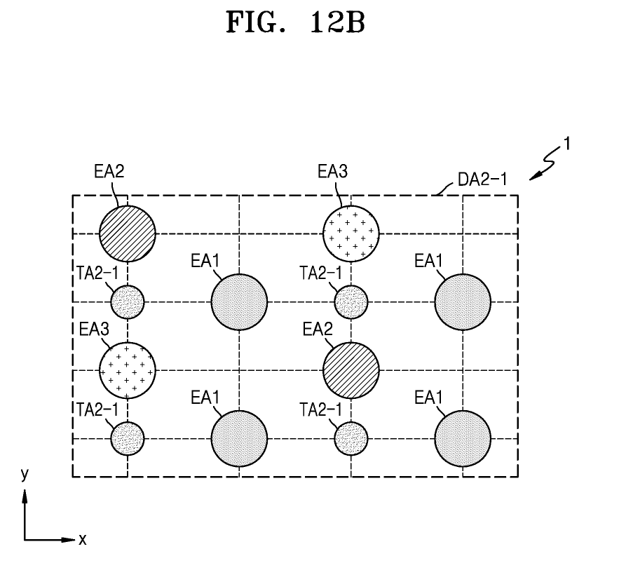

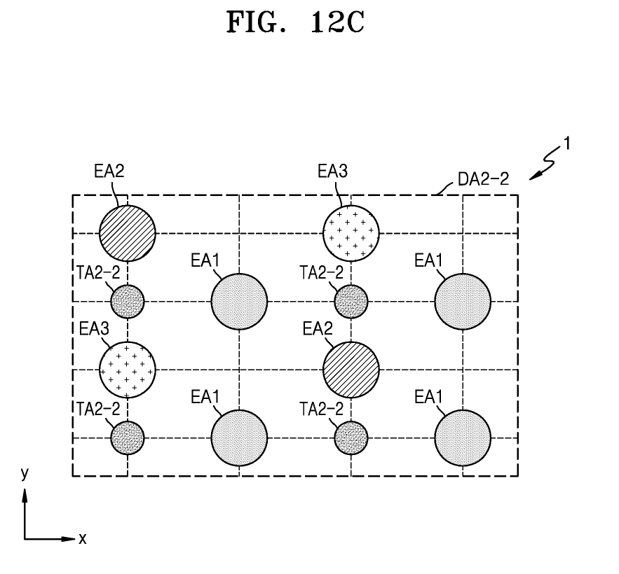

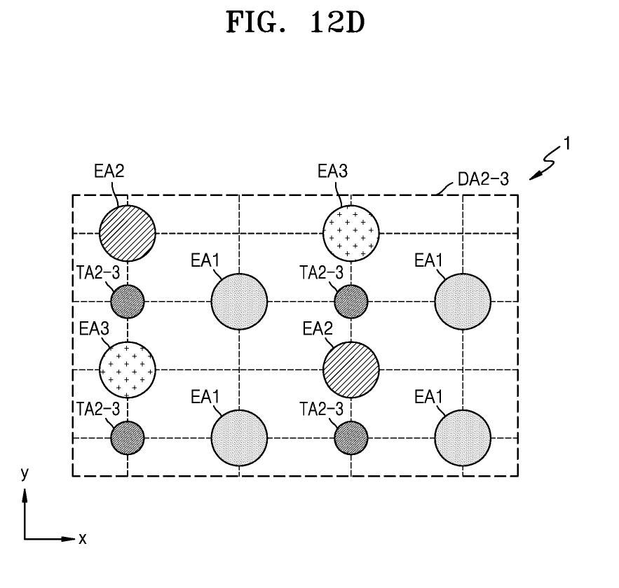

FIGS. 12A to 12D are schematic plan views of an embodiment of the display device 1.

Specifically, FIG. 12A is an enlarged view of a region B of FIG. 10 in the display device 1, FIG. 12B is an enlarged view of a region C of FIG. 10 in the display device 1, FIG. 12C is an enlarged view of a region D of FIG. 10 in the display device 1, and FIG. 12D is an enlarged view of a region E of FIG. 10 in the display device 1.

In FIGS. 12A to 12D, the same reference numerals as those of FIGS. 4 to 9 denote the same members, and thus, repeated descriptions thereof are omitted.

Referring to FIGS. 12A to 12D, the first to third emission areas EA1, EA2, and EA3 may be disposed in the display area DA. Specifically, the first to third emission areas EA1, EA2, and EA3 may be disposed in each of the first display area DA1 and the second display area DA2.

As shown in FIG. 12A, the first transmission area TA1 may be disposed in the first display area DA1. As shown in FIG. 12B, the second-1 transmission area TA2-1 may be disposed in the second-1 display area DA2-1. As shown in FIG. 12C, the second-2 transmission area TA2-2 may be disposed in the second-2 display area DA2-2. As shown in FIG. 12D, the second-3 transmission area TA2-3 may be disposed in the second-3 display area DA2-3.

As shown in FIG. 12A, in the first display area DA1, the plurality of second emission areas EA2 and the plurality of third emission areas EA3 may be alternately disposed in one row. In the first display area DA1, the plurality of first transmission areas TA1 and the plurality of first emission areas EA1 may be alternately disposed in another row. In the first display area DA1, the plurality of second emission areas EA2, the plurality of first transmission areas TA1, the plurality of third emission areas EA3, and the plurality of first transmission areas TA1 may be alternately disposed in one column. In the first display area DA1, the plurality of first emission areas EA1 may be disposed apart from each other in another column.

In the first display area DA1, with respect to one first transmission area TA1, two first emission areas EA1 next (adjacent) to each other in the first direction (e.g., the x axis direction and/or the -x axis direction) may be disposed. In addition, in the first display area DA1, with respect to one first transmission area TA1, one second emission area EA2 and one third emission area EA3 next (adjacent) to each other in the second direction (e.g., the y axis direction and/or the -y axis direction) may be disposed. That is, in the first display area DA1, one second emission area EA2, one third emission area EA3, and two first emission areas EA1 may surround one first transmission area TA1.

As shown in FIG. 12B, in the second-1 display area DA2-1, the plurality of second emission areas EA2 and the plurality of third emission areas EA3 may be alternately disposed in one row. In the second-1 display area DA2-1, the plurality of second-1 transmission areas TA2-1 and the plurality of first emission areas EA1 may be alternately disposed in another row. In the second-1 display area DA2-1, the plurality of second emission areas EA2, the plurality of second-1 transmission areas TA2-1, the plurality of third emission areas EA3, and the plurality of second-1 transmission areas TA2-1 may be alternately disposed in one column. In the second-1 display area DA2-1, the plurality of first emission areas EA1 may be disposed apart from each other in another column.

In the second-1 display area DA2-1, with respect to one second-1 transmission area TA2-1, two first emission areas EA1 next (adjacent) to each other in the first direction (e.g., the x axis direction and/or the -x axis direction) may be disposed. In addition, in the second-1 display area DA2-1, with respect to one second-1 transmission area TA2-1, one second emission area EA2 and one third emission area EA3 next (adjacent) to each other in the second direction (e.g., the y axis direction and/or the -y axis direction) may be disposed. That is, in the second-1 display area DA2-1, one second emission area EA2, one third emission area EA3, and two first emission areas EA1 may surround one second-1 transmission area TA2-1.

As shown in FIG. 12C, in the second-2 display area DA2-2, the plurality of second emission areas EA2 and the plurality of third emission areas EA3 may be alternately disposed in one row. In the second-2 display area DA2-2, the plurality of second-2 transmission areas TA2-2 and the plurality of first emission areas EA1 may be alternately disposed in another row. In the second-2 display area DA2-2, the plurality of second emission areas EA2, the plurality of second-2 transmission areas TA2-2, the plurality of third emission areas EA3, and the plurality of second-2 transmission areas TA2-2 may be alternately disposed in one column. In the second-2 display area DA2-2, the plurality of first emission areas EA1 may be disposed apart from each other in another column.

In the second-2 display area DA2-2, with respect to one second-2 transmission area TA2-2, two first emission areas EA1 next (adjacent) to each other in the first direction (e.g., the x axis direction and/or the -x axis direction) may be disposed. In addition, in the second-2 display area DA2-2, with respect to one second-2 transmission area TA2-2, one second emission area EA2 and one third emission area EA3 next (adjacent) to each other in the second direction (e.g., the y axis direction and/or the -y axis direction) may be disposed. That is, in the second-2 display area DA2-2, one second emission area EA2, one third emission area EA3, and two first emission areas EA1 may surround one second-2 transmission area TA2-2.

As shown in FIG. 12D, in the second-3 display area DA2-3, the plurality of second emission areas EA2 and the plurality of third emission areas EA3 may be alternately disposed in one row. In the second-3 display area DA2-3, the plurality of second-3 transmission areas TA2-3 and the plurality of first emission areas EA1 may be alternately disposed in another row. In the second-3 display area DA2-3, the plurality of second emission areas EA2, the plurality of second-3 transmission areas TA2-3, the plurality of third emission areas EA3, and the plurality of second-3 transmission areas TA2-3 may be alternately disposed in one column. In the second-3 display area DA2-3, the plurality of first emission areas EA1 may be disposed apart from each other in another column.

In the second-3 display area DA2-3, with respect to one second-3 transmission area TA2-3, two first emission areas EA1 next (adjacent) to each other in the first direction (e.g., the x axis direction and/or the -x axis direction) may be disposed. In addition, in the second-3 display area DA2-3, with respect to one second-3 transmission area TA2-3, one second emission area EA2 and one third emission area EA3 next (adjacent) to each other in the second direction (e.g., the y axis direction and/or the -y axis direction) may be disposed. That is, in the second-3 display area DA2-3, one second emission area EA2, one third emission area EA3, and two first emission areas EA1 may surround one second-3 transmission area TA2-3.

Referring to FIGS. 12A to 12D, in a position overlapping the second-1 transmission area TA2-1, an opening is not defined in the bank layer 123 (refer to FIG. 7), and an opening may be defined in the light-blocking layer 610 (refer to FIG. 7). In addition, in a position overlapping the second-2 transmission area TA2-2, an opening is defined in the bank layer 123 (refer to FIG. 7), and an opening may not be defined in the light-blocking layer 610 (refer to FIG. 8A). In addition, in positions overlapping a plurality of second-3 transmission areas TA2-3, an opening may not be defined in each of the bank layer 123 (refer to FIG. 9) and the light-blocking layer 610 (refer to FIG. 9).

Accordingly, an external light reflectance of the first transmission area TA1 may be greater than an external light reflectance of the second-1 transmission area TA2-1. In addition, an external light reflectance of the second-1 transmission area TA2-1 may be greater than an external light reflectance of the second-2 transmission area TA2-2. In addition, an external light reflectance of the second-2 transmission area TA2-2 may be greater than an external light reflectance of the second-3 transmission area TA2-3.

In this structure, external light reflectance of the first display area DA1, the second-1 display area DA2-1, the second-2 display area DA2-2, and the second-3 display area DA2-3 may be gradually reduced. Accordingly, a phenomenon that a boundary line is visible inside the display area DA due to a rapid difference in external light reflectance may be reduced.

In an embodiment, although not shown in FIGS. 12A to 12D, at least two of the second-1 transmission area TA2-1, the second-2 transmission area TA2-2, and the second-3 transmission area TA2-3 may be mixedly disposed in at least one of the second-1 display area DA2-1, the second-2 display area DA2-2, and the second-3 display area DA2-3. In an embodiment, the second-1 transmission area TA2-1 and the second-2 transmission area TA2-2 may be mixedly disposed in the second-1 display area DA2-1. The second-1 transmission area TA2-1 and the second-2 transmission area TA2-2 may be mixedly disposed in the second-2 display area DA2-2, and the density (the number per unit area) of the second-2 transmission area TA2-2 in the second-2 display area DA2-2 may be greater than the density of the second-2 transmission area TA2-2 in the second-1 display area DA2-1. Only the second-3 transmission area TA2-3 may be disposed in the second-3 display area DA2-3. The arrangement of the second-1 transmission area TA2-1, the second-2 transmission area TA2-2, and the second-3 transmission area TA2-3 is not limited to the above embodiment, and may be various.

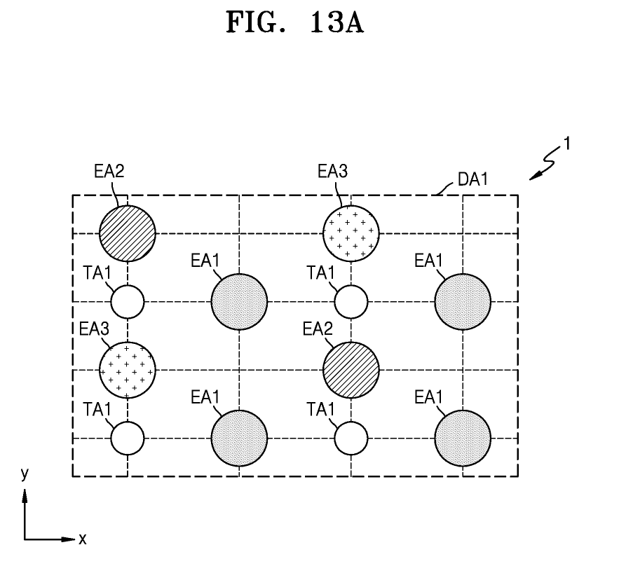

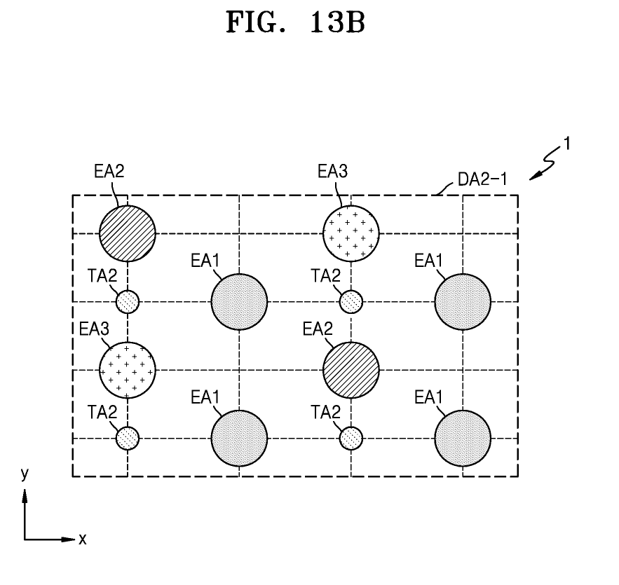

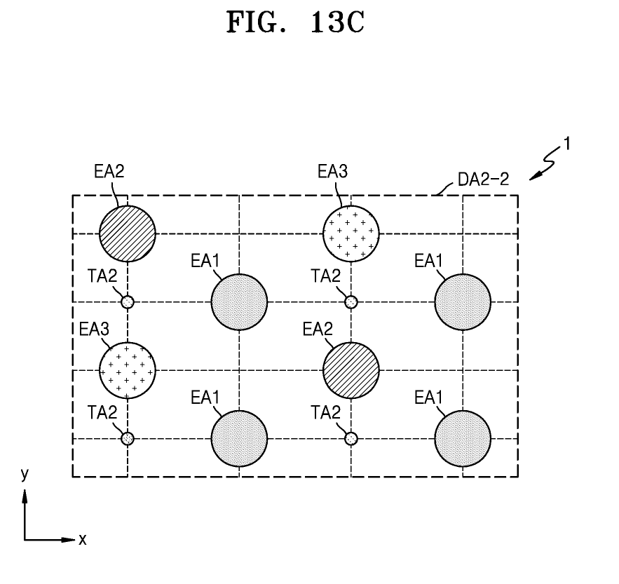

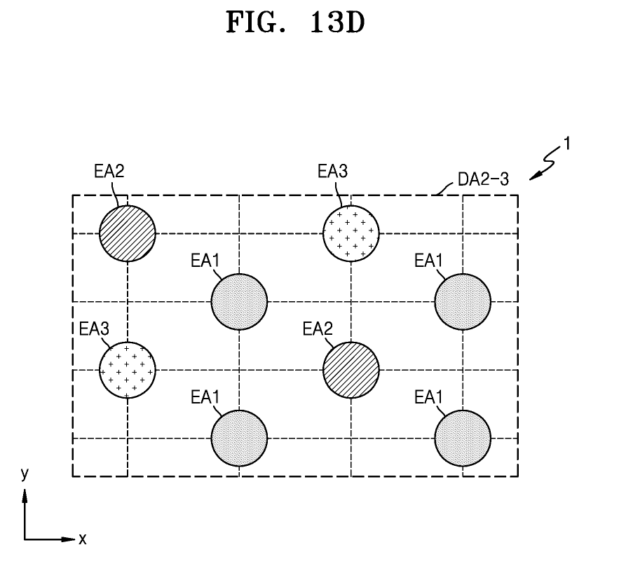

FIGS. 13A to 13D are schematic plan views of an embodiment of the display device 1.

Specifically, FIG. 13A is an enlarged view of the region B of FIG. 10 in the display device 1, FIG. 13B is an enlarged view of the region C of FIG. 10 in the display device 1, FIG. 13C is an enlarged view of the region D of FIG. 10 in the display device 1, and FIG. 13D is an enlarged view of the region E of FIG. 10 in the display device 1.

In FIGS. 13A to 13D, the same reference numerals as those of FIGS. 4 to 9 denote the same members, and thus, repeated descriptions thereof are omitted.

Referring to FIGS. 13A to 13D, the first to third emission areas EA1, EA2, and EA3 may be disposed in the display area DA. Specifically, the first to third emission areas EA1, EA2, and EA3 may be disposed in each of the first display area DA1 and the second display area DA2.

In an embodiment, as shown in FIG. 13A, the first transmission area TA1 may be disposed in the first display area DA1. In an embodiment, as shown in FIGS. 13B to 13D, the second transmission area TA2 may be disposed in the second display area DA2. In an embodiment, the first transmission area TA1 may be disposed in the first display area DA1, and the second transmission area TA2 may be disposed in the second-1 display area DA2-1 and the second-2 display area DA2-2. The second transmission area TA2 may include at least one of the second-1 transmission area TA2-1 (refer to FIG. 7), the second-2 transmission area TA2-2 (refer to FIG. 8A), and the second-3 transmission area TA2-3 (refer to FIG. 9).

As shown in FIG. 13A, in the first display area DA1, the plurality of second emission areas EA2 and the plurality of third emission areas EA3 may be alternately disposed in one row. In the first display area DA1, the plurality of first transmission areas TA1 and the plurality of first emission areas EA1 may be alternately disposed in another row. In the first display area DA1, the plurality of second emission areas EA2, the plurality of first transmission areas TA1, the plurality of third emission areas EA3, and the plurality of first transmission areas TA1 may be alternately disposed in one column. In the first display area DA1, the plurality of first emission areas EA1 may be disposed apart from each other in another column.

In the first display area DA1, with respect to one first transmission area TA1, two first emission areas EA1 next (adjacent) to each other in the first direction (e.g., the x axis direction and/or the -x axis direction) may be disposed. In addition, in the first display area DA1, with respect to one first transmission area TA1, one second emission area EA2 and one third emission area EA3 next (adjacent) to each other in the second direction (e.g., the y axis direction and/or the -y axis direction) may be disposed. That is, in the first display area DA1, one second emission area EA2, one third emission area EA3, and two first emission areas EA1 may surround one first transmission area TA1.

As shown in FIGS. 13B and 13C, in the second-1 display area DA2-1 and the second-2 display area DA2-2, the plurality of second emission areas EA2 and the plurality of third emission areas EA3 may be alternately disposed in one row. In the second-1 display area DA2-1 and the second-2 display area DA2-2, the plurality of second transmission areas TA2 and the plurality of first emission areas EA1 may be alternately disposed in another row. In the second-1 display area DA2-1 and the second-2 display area DA2-2, the plurality of second emission areas EA2, the plurality of second transmission areas TA2, the plurality of third emission areas EA3, and the plurality of second transmission areas TA2 may be alternately disposed in one column. In the second-1 display area DA2-1 and the second-2 display area DA2-2, the plurality of first emission areas EA1 may be disposed apart from each other in one column.

In the second-1 display area DA2-1 and the second-2 display area DA2-2, with respect to one second transmission area TA2, two first emission areas EA1 next (adjacent) to each other in the first direction (e.g., the x axis direction and/or the -x axis direction) may be disposed. In addition, in the second-1 display area DA2-1 and the second-2 display area DA2-2, with respect to one second transmission area TA2, one second emission area EA2 and one third emission area EA3 next (adjacent) to each other in the second direction (e.g., the y axis direction and/or the -y axis direction) may be disposed. That is, in the second-1 display area DA2-1 and the second-2 display area DA2-2, one second emission area EA2, one third emission area EA3, and two first emission area EA1 may surround one second transmission area TA2.

The sizes of the plurality of first transmission areas TA1 may be greater than the sizes of the second transmission areas TA2. The areas of the plurality of first transmission areas TA1 may be greater than the areas of the second transmission areas TA2. In addition, the sizes of the second transmission areas TA2 disposed in the second-1 display area DA2-1 may be greater than the sizes of the second transmission areas TA2 disposed in the second-2 display area DA2-2. The areas of the plurality of second-1 transmission areas TA2-1 disposed in the second-1 display area DA2-1 may be greater than the sizes of the plurality of second-2 transmission areas TA2-2 disposed in the second-2 display area DA2-2. The sizes of the plurality of second transmission areas TA2 may be gradually reduced away from the first display area DA1.

As shown in FIG. 13D, in the second-3 display area DA2-3, the plurality of second emission areas EA2 and the plurality of third emission areas EA3 may be alternately disposed in one row. In the second-3 display area DA2-3, the plurality of first emission areas EA1 may be disposed apart from each other in another row. In the second-3 display area DA2-3, the plurality of second emission areas EA2 and the plurality of third emission areas EA3 may be alternately disposed in another column. In the second-3 display area DA2-3, the plurality of first emission areas EA1 may be disposed apart from each other in another column. In the second-3 display area DA2-3, the first transmission area TA1 and the second transmission area TA2 may not be disposed.

Accordingly, an external light reflectance of the first display area DA1 may be greater than an external light reflectance of the second-1 display area DA2-1. In addition, an external light reflectance of the second-1 display area DA2-1 may be greater than an external light reflectance of the second-2 display area DA2-2. In addition, an external light reflectance of the second-2 display area DA2-2 may be greater than an external light reflectance of the second-3 display area DA2-3.

In this structure, external light reflectance of the first display area DA1, the second-1 display area DA2-1, the second-2 display area DA2-2, and the second-3 display area DA2-3 may be gradually reduced. Accordingly, a phenomenon that a boundary line is visible inside the display area DA due to a rapid difference in external light reflectance may be reduced.

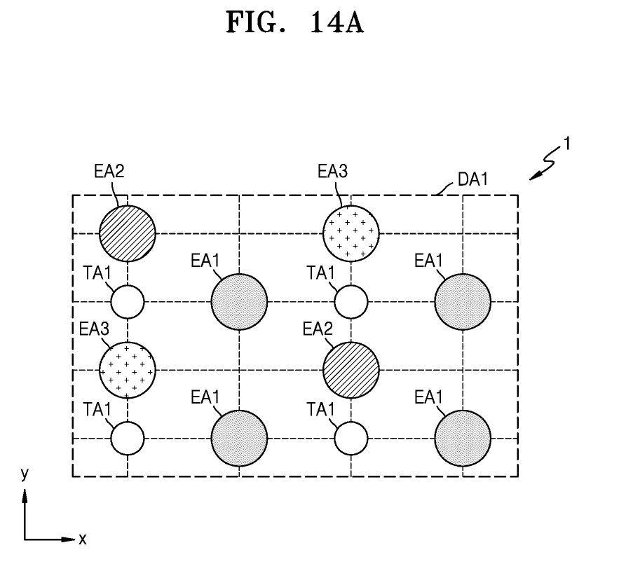

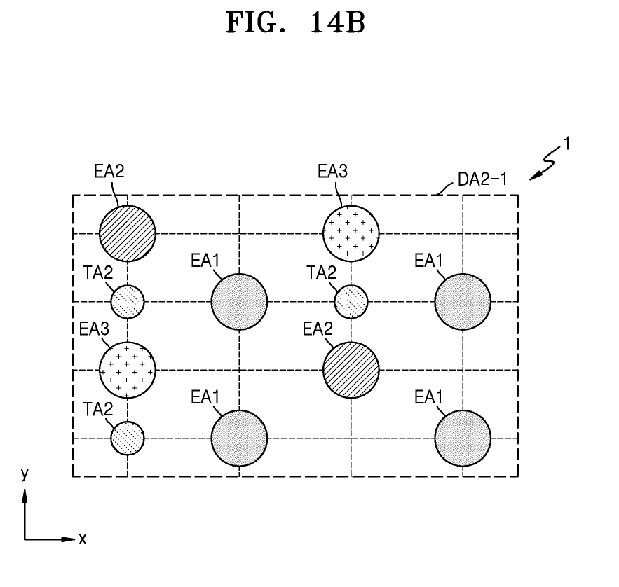

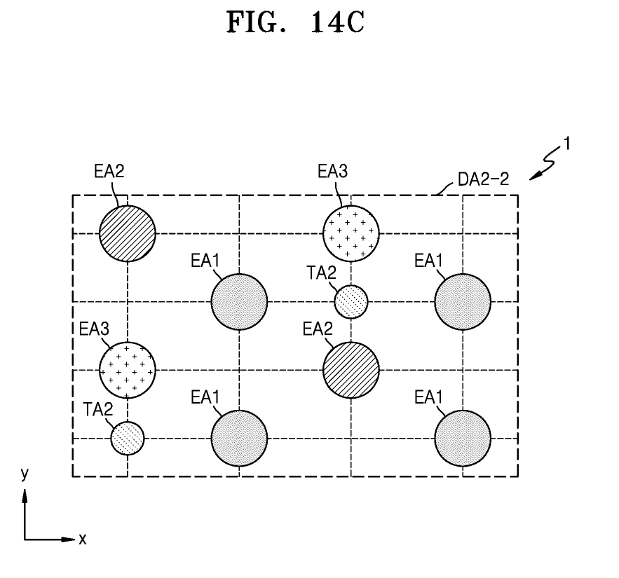

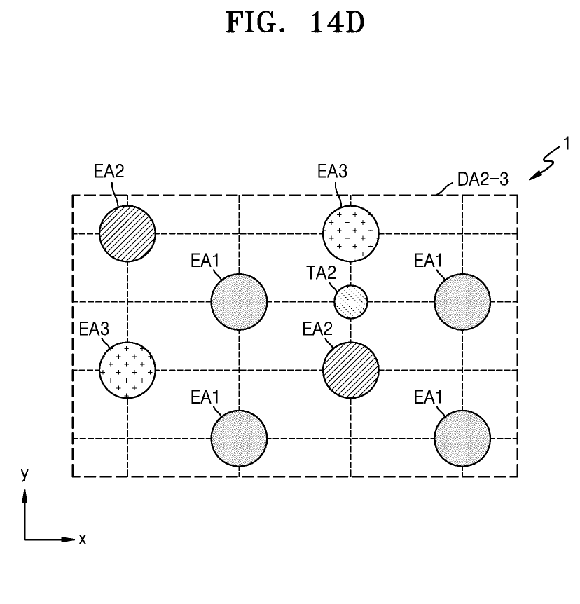

FIGS. 14A to 14D are schematic plan views of an embodiment of the display device 1.

Specifically, FIG. 14A is an enlarged view of the region B of FIG. 10 in the display device 1, FIG. 14B is an enlarged view of the region C of FIG. 10 in the display device 1, FIG. 14C is an enlarged view of the region D of FIG. 10 in the display device 1, and FIG. 14D is an enlarged view of the region E of FIG. 10 in the display device 1.

In FIGS. 14A to 14D, the same reference numerals as those of FIGS. 4 to 9 denote the same members, and thus, repeated descriptions thereof are omitted.

Referring to FIGS. 14A to 14D, the first to third emission areas EA1, EA2, and EA3 may be disposed in the display area DA. Specifically, the first to third emission areas EA1, EA2, and EA3 may be disposed in each of the first display area DA1 and the second display area DA2.

In an embodiment, as shown in FIG. 14A, the first transmission area TA1 may be disposed in the first display area DA1. In an embodiment, as shown in FIGS. 14B to 14D, the second transmission area TA2 may be disposed in the second display area DA2. In an embodiment, the first transmission area TA1 may be disposed in the first display area DA1, and the second transmission area TA2 may be disposed in the second-1 display area DA2-1, the second-2 display area DA2-2, and the second-3 display area DA2-3. The second transmission area TA2 may include at least one of the second-1 transmission area TA2-1 (refer to FIG. 7), the second-2 transmission area TA2-2 (refer to FIG. 8), and the second-3 transmission area TA2-3 (refer to FIG. 9).

A region shown in FIGS. 14A to 14D may be defined as a unit area. The number (e.g., 3, 2, or 1) of the plurality of second transmission areas TA2 per unit area in the second display area DA2 may be less than the number (e.g., 4) of the plurality of first transmission areas TA1 per unit area in the first display area DA1. The number of the plurality of second transmission areas TA2 per unit area may be gradually reduced away from the first display area DA1. The number (e.g., 2) of the plurality of second transmission areas TA2 per unit area in the second-2 display area DA2-2 may be less than the number (e.g., 3) of the plurality of second transmission areas TA2 per unit area in the second-1 display area DA2-1. The number (e.g., 1) of the plurality of second transmission areas TA2 per unit area in the second-3 display area DA2-3 may be less than the number (e.g., 2) of the plurality of second transmission areas TA2 per unit area in the second-2 display area DA2-2.

Accordingly, an external light reflectance of the first display area DA1 may be greater than an external light reflectance of the second-1 display area DA2-1. In addition, an external light reflectance of the second-1 display area DA2-1 may be greater than an external light reflectance of the second-2 display area DA2-2. In addition, an external light reflectance of the second-2 display area DA2-2 may be greater than an external light reflectance of the second-3 display area DA2-3.

In this structure, external light reflectance of the first display area DA1, the second-1 display area DA2-1, the second-2 display area DA2-2, and the second-3 display area DA2-3 may be gradually reduced. Accordingly, a phenomenon that a boundary line is visible inside the display area DA due to a rapid difference in external light reflectance may be reduced.

FIG. 15 is a schematic plan view of an embodiment of the display device 1.

In FIG. 15, the same reference numerals as those of FIGS. 10 to 14D denote the same members, and thus, repeated descriptions thereof are omitted.

Referring to FIG. 15, the display device 1 may include the display area DA, and the non-display area NDA outside the display area DA.

The display area DA may include the first display area DA1, the second display area DA2, and the third display area DA3. The first display area DA1 may be a region in which a component for adding various functions to the display device 1. The first display area DA1 may correspond to a component area. The third display area DA3 may be a region of the display area DA disposed next (adjacent) to the non-display area NDA. The second display area DA2 may be a region disposed between the first display area DA1 and the third display area DA3. In an embodiment, the second display area DA2 may surround the first display area DA1, the third display area DA3 may surround the second display area DA2, and the non-display area NDA may surround the third display area DA3. However, this is just an example, and the arrangement of the display area DA and the non-display area NDA is not limited thereto. Because the first display area DA1, the second display area DA2, and the third display area DA3 are described in detail with reference to FIGS. 10 to 15, detailed descriptions thereof are omitted.

Because the third display area DA3 is a region disposed in the outer portion of the display area DA, the thickness of the color filters in the third display area DA3 may be thinner than the thickness of the color filters in the second display area DA2. Accordingly, a light transmittance of the color filters disposed in the third display area DA3 may be greater than a light transmittance of the color filters disposed in the second display area DA2. Accordingly, a bright band phenomenon occurring between the second display area DA2 and the third display area DA3 may be reduced by adjusting an external light reflectance in the third display area DA3 using the structure described with reference to FIGS. 10 to 14D.

In an embodiment, the embodiment described with reference to FIGS. 12A to 12D is applicable. In an embodiment, in a position next (adjacent) to the boundary between the second display area DA2 and the third display area DA3, in the case where the second-1 transmission area TA2-1 (refer to FIG. 7) is disposed in the second display area DA2, the second-2 transmission area TA2-2 (refer to FIG. 8A) may be disposed in the third display area DA3. In an alternative embodiment, in a position next (adjacent) to the boundary between the second display area DA2 and the third display area DA3, in the case where the second-2 transmission area TA2-2 (refer to FIG. 8A) is disposed in the second display area DA2, the second-3 transmission area TA2-3 (refer to FIG. 9) may be disposed in the third display area DA3. In an alternative embodiment, in a position next (adjacent) to the boundary between the second display area DA2 and the third display area DA3, at least two of the second-1 transmission area TA2-1 (refer to FIG. 7), the second-2 transmission area TA2-2 (refer to FIG. 8A), and the second-3 transmission area TA2-3 (refer to FIG. 9) may be mixedly disposed in each of the second display area DA2 and the third display area DA3.

In an embodiment, the embodiment described with reference to FIGS. 13A to 13D is applicable. In an embodiment, in a position next (adjacent) to the boundary between the second display area DA2 and the third display area DA3, the size of the second transmission area TA2 (refer to FIG. 6) disposed in the third display area DA3 may be less than the size of the second transmission area TA2 (refer to FIG. 6) disposed in the second display area DA2.

In an embodiment, the embodiment described with reference to FIGS. 14A to 14D is applicable. In an embodiment, in a position next (adjacent) to the boundary between the second display area DA2 and the third display area DA3, the density (the number per unit area) of the second transmission area TA2 (refer to FIG. 6) disposed in the third display area DA3 may be less than the density of the second transmission area TA2 (refer to FIG. 6) disposed in the second display area DA2.

In this structure, in a position next (adjacent) to the boundary between the second display area DA2 and the third display area DA3, a difference in external light reflectance between the second display area DA2 and the third display area DA3 may be reduced.

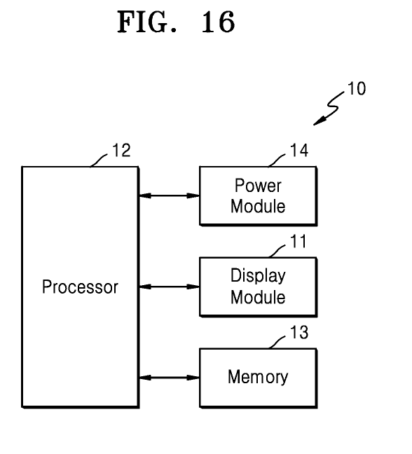

FIG. 16 is a block diagram of an embodiment of an electronic device 10.

Referring to FIG. 16, the electronic device 10 in an embodiment may include a display module 11, a processor 12, a memory 13, and a power module 14.

The processor 12 may include at least one of a central processing unit (“CPU”), an application processor (“AP”), a graphic processing unit (“GPU”), a communication processor (“CP”), an image signal processor (“ISP”), and a controller.

The memory 13 may store data information desired for operations of the processor 12 or the display module 11. When the processor 12 executes an application stored in the memory 13, an image data signal and/or an input control signal may be transferred to the display module 11, and the display module 11 may process a provided signal and output image information through a display screen.

The power module 14 may include a power supply module such as a power adapter or a battery unit, and a power converting module converting power supplied by the power supply module and generating power desired for operations of the electronic device 10.

At least one of elements of the electronic device 10 may be included in the display device 1 in the embodiments. In addition, some of individual modules functionally included in one module may be included in the display device 1, and some other may be provided separately from the display device 1. In an embodiment, the display device 1 may include the display module 11, and the processor 12, the memory 13, and the power module 14 may be provided within the electronic device 10 instead of the display device 1.

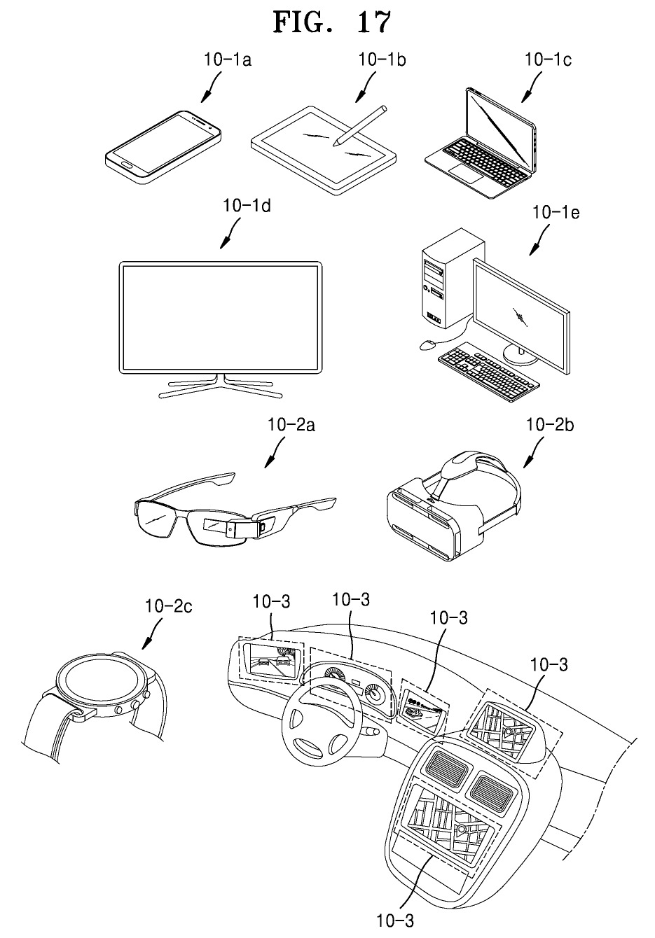

FIG. 17 is a schematic view of embodiments of electronic devices.

Referring to FIG. 17, the various electronic devices employing the display device 1 in the embodiments may include not only electronic devices for displaying images, such as a smartphone 10-1a, a tablet personal computer 10-1b, a laptop computer 10-1c, a television (“TV”) 10-1d, and a desk monitor 10-1e, but also wearable electronic devices including a display module, such as a smart glasses 10-2a, a head mount display 10-2b, and a smart watch 10-2c, and vehicle electronic devices 10-3 including a display module, such as an instrument panel of an automobile, a center fascia, a center information display (“CID”) disposed on a dashboard, and a room mirror display.

By embodiments, the quality of the display device may be improved.

Effects of the disclosure are not limited to the above mentioned effects and other effects not mentioned may be clearly understood by those of ordinary skill in the art from the following claims.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. A display device comprising:
a first display area including a plurality of first transmission areas;
a second display area including a plurality of second transmission areas
a substrate;
a pixel electrode disposed on the substrate;
an emission layer disposed on the pixel electrode;
a bank layer covering at least a portion of the pixel electrode; and
a light-blocking layer disposed on the bank layer,
wherein an opening is defined in each of the bank layer and the light-blocking layer, at positions overlapping the plurality of first transmission areas, and
wherein an opening is defined in one of the bank layer and the light-blocking layer, at positions overlapping the plurality of second transmission areas.

2. The display device of claim 1, wherein external light reflectance in a first transmission area of the plurality of first transmission areas is greater than external light reflectance in a second transmission area of the plurality of second transmission areas.

3. The display device of claim 1, wherein infrared rays are transmitted through each of a first transmission area of the plurality of first transmission areas and a second transmission area of the plurality of second transmission areas.

4. The display device of claim 1, wherein a size of the plurality of second transmission areas gradually decreases with increasing distance from the first display area.

5. The display device of claim 1, wherein a number of the plurality of second transmission areas per unit area gradually decreases with increasing distance from the first display area.

6. The display device of claim 1, wherein the second display area includes a second-1 display area, a second-2 display area, and a second-3 display area, which are arranged in order of increasing distance from the first display area,
wherein the plurality of second transmission areas include a plurality of second-1 transmission areas disposed in the second-1 display area, a plurality of second-2 transmission areas disposed in the second-2 display area, and a plurality of second-3 transmission areas disposed in the second-3 display area,
wherein external light reflectance in a second-1 transmission area of the plurality of second-1 transmission areas is greater than external light reflectance in the second-2 transmission area, and
wherein the external light reflectance in the second-2 transmission area is greater than external light reflectance in the second-3 transmission area.

7. The display device of claim 6, wherein an opening is defined in the bank layer and an opening is not defined in the light-blocking layer, at positions overlapping the plurality of second-1 transmission areas, and
wherein an opening is defined in the light-blocking layer and an opening is not defined in the bank layer, at positions overlapping the plurality of second-2 transmission areas.

8. The display device of claim 6, wherein an opening is not defined in each of the bank layer and the light-blocking layer, at positions overlapping the plurality of second-3 transmission areas.

9. The display device of claim 1, further comprising a color filter disposed in the light-blocking layer, wherein the color filter is spaced apart from each of the plurality of first transmission areas and the plurality of second transmission areas.

10. The display device of claim 1, wherein the emission layer is spaced apart from each of the plurality of first transmission areas and the plurality of second transmission areas.

11. An electronic device comprising:
a display device comprising:
a first display area including a plurality of first transmission areas are;
a second display area including a plurality of second transmission areas;
a first component overlapping the plurality of first transmission areas,
a substrate;
a pixel electrode disposed on the substrate;
an emission layer disposed on the pixel electrode;
a bank layer covering at least a portion of the pixel electrode; and
a light-blocking layer disposed on the bank layer,
wherein an opening is defined in each of the bank layer and the light-blocking layer, at positions overlapping the plurality of first transmission areas, and
wherein an opening is defined in one of the bank layer and the light-blocking layer, at positions overlapping the plurality of second transmission areas.

12. The electronic device of claim 11, wherein the first component includes an illuminance sensor.

13. The electronic device of claim 11, further comprising a second component disposed to overlap the plurality of second transmission areas, wherein the second component includes an infrared sensor.

14. The electronic device of claim 11, wherein external light reflectance in a first transmission area of the plurality of first transmission areas of the display device is greater than external light reflectance in a second transmission area of the plurality of second transmission areas of the display device.

15. The electronic device of claim 11, wherein infrared rays are transmitted through each of a first transmission area of the plurality of first transmission areas and a second transmission area of the display device of the plurality of second transmission areas.

16. The electronic device of claim 11, wherein a size of the plurality of second transmission areas gradually decreases with increasing distance from the first display area.

17. The electronic device of claim 11, wherein a number of the plurality of second transmission areas per unit area gradually decreases with increasing distance from the first display area.

18. The electronic device of claim 11, wherein the second display area includes a second-1 display area, a second-2 display area, and a second-3 display area, which are arranged in order of increasing distance from the first display area,
wherein the plurality of second transmission areas include a plurality of second-1 transmission areas disposed in the second-1 display area, a plurality of second-2 transmission areas disposed in the second-2 display area, and a plurality of second-3 transmission areas disposed in the second-3 display area,
wherein external light reflectance in a second-1 transmission area of the plurality of second-1 transmission areas of the display device is greater than external light reflectance in a second-2 transmission area of the plurality of second-2 transmission areas of the display device, and
wherein the external light reflectance in the second-2 transmission area of the display device is greater than external light reflectance in a second-3 transmission area of the plurality of second-3 transmission areas of the display device.

19. The electronic device of claim 18, wherein an opening is defined in the bank layer and an opening is not defined in the light-blocking layer, at positions overlapping the plurality of second-1 transmission areas, and
wherein an opening is defined in the light-blocking layer and an opening is not defined in the bank layer, at positions overlapping the plurality of second-2 transmission areas.

20. The electronic device of claim 18, wherein an opening is not defined in each of the bank layer and the light-blocking layer, at positions overlapping the plurality of second-3 transmission areas.
